(19) United States
(12) Patent Application Publication
(10) Pub. No.: US 2025/0338542 A1
(43) Pub. Date: Oct. 30, 2025

(54) SEMICONDUCTOR DEVICE

(71) Applicant: Renesas Electronics Corporation, Tokyo (JP)

(72) Inventor: Takahiro MORI, Tokyo (JP)

(21) Appl. No.: 19/097,335

(22) Filed: Apr. 1, 2025

(30) Foreign Application Priority Data
Apr. 30, 2024 (JP) 2024-073929

(51) Int. Cl. H10D 30/60; H10D 30/65; H10D 62/10

(52) U.S. Cl. CPC H10D 30/603; H10D 30/65; H10D 62/107; H10D 62/112

(57) ABSTRACT

A semiconductor device includes an offset drain region and a p-type well. In a gate length direction of a gate electrode, a first distance between the offset drain region and a first portion of the p-type well is larger than a second distance between the offset drain region and a second portion of the p-type well. The semiconductor device includes an n-type semiconductor region formed in a portion of an epitaxial layer located between the offset drain region and a source region.

### CROSS-REFERENCE TO RELATED APPLICATION

The disclosure of Japanese Patent Application No. 2024-073929 filed on Apr. 30, 2024, including the specification, drawings and abstract is incorporated herein by reference in its entirety.

### BACKGROUND

The present invention relates to a semiconductor device, and relates to a technique effectively applied to, for example, a semiconductor device including a laterally diffused metal oxide semiconductor field effect transistor (LDMOSFET).

There is disclosed technique listed below.
[Patent Document 1] Japanese Unexamined Patent Application Publication No. 2020-129597

The Patent Document 1 discloses a technique relating to the semiconductor device including the LDMOSFET.

### SUMMARY

In the semiconductor device including the LDMOSFET, for example, it is desired to decrease a threshold voltage of the LDMOSFET without decreasing an off-state breakdown voltage of the LDMOSFET.

Other problems and novel features will be apparent from the description of the present specification and the accompanying drawings.

In an embodiment, a semiconductor device includes a p-type well having a first portion and a second portion and an n-type semiconductor region formed in a semiconductor substrate and arranged between an offset drain region and a source region.

According to a semiconductor device including an LDMOSFET according to an embodiment, it is possible to decrease the threshold voltage of the LDMOSFET without decreasing the off-state breakdown voltage of the LDMOSFET.

### BRIEF DESCRIPTIONS OF THE DRAWINGS

FIG. 1 is a diagram illustrating a configuration of a constant current source made of a resistance element.

FIG. 2 is a graph illustrating a current-voltage property in the constant current source illustrated in FIG. 1.

FIG. 3 is a diagram illustrating a configuration of a constant current source made of a combination of a depletion-type MOSFET and a resistance element.

FIG. 4 is a graph illustrating a current-voltage property in the constant current source illustrated in FIG. 3.

FIG. 5 is a plan view illustrating an LDMOSFET in a first related technique.

FIG. 6 is a cross-sectional view of the LDMOSFET along a line A-A illustrated in FIG. 5.

FIG. 7 is a cross-sectional view of the LDMOSFET along a line B-B illustrated in FIG. 5.

FIG. 8 is a cross-sectional view of the LDMOSFET along a line C-C illustrated in FIG. 5.

FIG. 9 is a plan view illustrating an LDMOSFET in a second related technique.

FIG. 10 is a cross-sectional view of the LDMOSFET along a line A-A illustrated in FIG. 9.

FIG. 11 is a cross-sectional view of the LDMOSFET along a line B-B illustrated in FIG. 9.

FIG. 12 is a cross-sectional view of the LDMOSFET along a line C-C illustrated in FIG. 9.

FIG. 13 is a plan view illustrating an LDMOSFET according to a first embodiment.

FIG. 14 is a cross-sectional view of the LDMOSFET along a line A-A illustrated in FIG. 13.

FIG. 15 is a cross-sectional view of the LDMOSFET along a line B-B illustrated in FIG. 13.

FIG. 16 is a cross-sectional view of the LDMOSFET along a line C-C illustrated in FIG. 13.

FIG. 17 is a plan view illustrating an LDMOSFET according to a modification example.

FIG. 18 is a cross-sectional view of the LDMOSFET along a line A-A illustrated in FIG. 17.

FIG. 19 is a cross-sectional view of the LDMOSFET along a line B-B illustrated in FIG. 17.

FIG. 20 is a diagram illustrating a manufacturing step of a semiconductor device according to a first embodiment.

FIG. 21 is a diagram illustrating a manufacturing step of the semiconductor device, continued from FIG. 20.

FIG. 22 is a diagram illustrating a manufacturing step of the semiconductor device, continued from FIG. 21.

FIG. 23 is a diagram illustrating a manufacturing step of the semiconductor device, continued from FIG. 22.

FIG. 24 is a diagram illustrating a manufacturing step of the semiconductor device, continued from FIG. 23.

FIG. 25 is a diagram illustrating a manufacturing step of the semiconductor device, continued from FIG. 24.

FIG. 26 is a diagram illustrating a configuration example of an opening for forming an n-type semiconductor region.

FIG. 27 is a diagram illustrating another configuration example of the opening for forming the n-type semiconductor region.

FIG. 28 is a diagram illustrating another configuration example of the opening for forming the n-type semiconductor region.

FIG. 29 is a plan view illustrating an LDMOSFET according to a second embodiment.

FIG. 30 is a cross-sectional view of the LDMOSFET along a line A-A illustrated in FIG. 29.

FIG. 31 is a cross-sectional view of the LDMOSFET along a line B-B illustrated in FIG. 29.

FIG. 32 is a cross-sectional view of the LDMOSFET along a line C-C illustrated in FIG. 29.

FIG. 33 is a plan view illustrating an LDMOSFET according to a third embodiment.

FIG. 34 is a cross-sectional view of the LDMOSFET along a line A-A illustrated in FIG. 33.

FIG. 35 is a cross-sectional view of the LDMOSFET along a line B-B illustrated in FIG. 33.

FIG. 36 is a cross-sectional view of the LDMOSFET along a line C-C illustrated in FIG. 33.

FIG. 37A is a diagram illustrating an impurity profile in an epitaxial layer in a depth direction in each of FIGS. 14 and 34.

FIG. 37B is a diagram illustrating an impurity profile in an epitaxial layer in a depth direction in each of FIGS. 15 and 35.

FIG. 38 is a diagram illustrating a main current and a sub-current flowing through a source region in an LDMOSFET including a p-type well made of a “ladder structure” having a first portion and a second portion and an n-type semiconductor region.

FIG. 39 is a graph illustrating a current-voltage property of the main current and a current-voltage property of the sub-current in the third embodiment.

### DETAILED DESCRIPTION

The same components are denoted by the same reference symbols over all the drawings for describing the embodiments, and the repetitive description thereof will be omitted. Note that hatching may be added even in a plan view for easy understanding of the drawings.

### Usability of Depletion-Type Field Effect Transistor

As field effect transistors, a depletion-type field effect transistor and an enhancement-type field effect transistor are known. When the “depletion-type field effect transistor” is an n-channel type field effect transistor, the “depletion-type field effect transistor” has a negative threshold voltage. On the other hand, when the “enhancement-type field effect transistor” is an n-channel type field effect transistor, the “enhancement-type field effect transistor” has a positive threshold voltage. The “depletion-type field effect transistor” is also referred to as a normally-on transistor. The “enhancement-type field effect transistor” is also referred to as a normally-off transistor.

For example, the depletion-type field effect transistor is used for a constant current source. The fact that power consumption of a semiconductor device can be decreased when the depletion-type field effect transistor is used for the constant current source will be explained below with reference to the drawings.

FIG. 1 is a diagram illustrating a configuration of a constant current source made of a resistance element R. In FIG. 1, the resistance element R is electrically connected to a circuit. A power supply voltage VIN is applied to the circuit via the resistance element R. In this case, a current I (=VIN/R) is supplied to the circuit.

In the constant current source illustrated in FIG. 1, a resistance value of the resistance element R needs to be set such that a current required for an operation of the circuit can be supplied even at a product minimum voltage Vmin of the power supply voltage VIN.

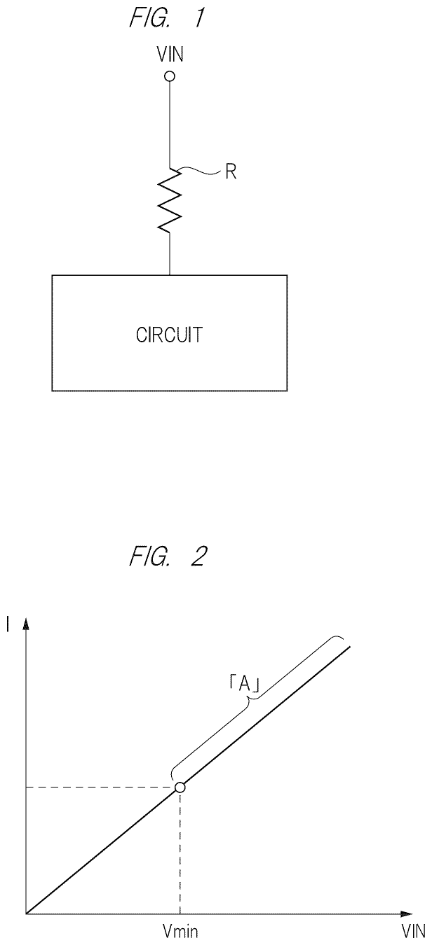

As indicated by a region “A” in FIG. 2, in the constant current source made of the resistance element R, increase in the magnitude of the power supply voltage VIN to be inputted to the resistance element R increases a current flowing through the circuit. That is, an excessive current flows through the circuit, and therefore, the power consumption of the semiconductor device using the constant current source made of the resistance element R increases.

FIG. 3 is a diagram illustrating a configuration of a constant current source made of a depletion-type MOSFET 10 and a resistance element R. In the FIG. 3, the depletion-type MOSFET 10 and the resistance element R are electrically connected to the circuit. The power supply voltage VIN is applied to the circuit via the depletion-type MOSFET 10 and the resistance element R. In this case, the power supply voltage VIN is applied to a drain of the depletion-type MOSFET 10. The resistance element R is connected to a source of the depletion-type MOSFET 10.

The current to be supplied to the circuit from the constant current source configured as described above depends on a current-voltage property of the depletion-type MOSFET 10. Specifically, as illustrated in FIG. 4, in a range where the power supply voltage VIN is low, the current to be supplied from the constant current source to the circuit increases in proportion to the magnitude of the power supply voltage VIN (a linear region). On the other hand, as illustrated in FIG. 4, in a range where the power supply voltage VIN is high, the current to be supplied from the constant current source to the circuit is almost constant regardless of the magnitude of the power supply voltage VIN (a saturation region). Therefore, in the range of the saturation region in the constant current source illustrated in FIG. 3, a current value hardly changes even if the magnitude of the power supply voltage VIN increases. An excessive current does not flow through the circuit, and therefore, the constant current source using the depletion-type MOSFET 10 can decrease the power consumption of the semiconductor device.

Here, in the constant current source using the depletion-type MOSFET 10, it is desirable to decrease a threshold voltage of the depletion-type MOSFET 10.

A reason why it is desirable to decrease the threshold voltage of the depletion-type MOSFET 10 will be described below.

The depletion-type MOSFET 10 made of an n-channel type MOSFET has a negative threshold voltage. Increase in an absolute value of the negative threshold voltage of the depletion-type MOSFET 10 can increase an operation margin of the constant current source using the depletion-type MOSFET 10.

For example, it is assumed that the threshold voltage of the depletion-type MOSFET 10 is “−0.3 V”. Also, it is assumed that a variation in the threshold voltage of the depletion-type MOSFET 10 depending on a process or a temperature is “±200 mV”. In this case, the absolute value of the threshold voltage of the depletion-type MOSFET 10 is minimized when the threshold voltage of the depletion-type MOSFET 10 is “−0.1 V”. On the other hand, the absolute value of the threshold voltage of the depletion-type MOSFET 10 is maximized when the threshold voltage of the depletion-type MOSFET 10 is “−0.5 V”. A start up time of the constant current source changes depending on whether the threshold voltage of the depletion-type MOSFET 10 is “−0.1 V” or “−0.5 V”. For example, when the resistance value of the resistance element R is 300 kΩ, a maximum current value is “1.67 μA”. On the other hand, a minimum current value is “333 nA”. A difference between the current values causes the variation in the start up time of the constant current source.

In this respect, it is assumed that the threshold voltage of the depletion-type MOSFET 10 is “−0.6 V”. Also, it is assumed that a variation in the threshold voltage of the depletion-type MOSFET 10 depending on a process or a temperature is “±200 mV”. In this case, the absolute value of the threshold voltage of the depletion-type MOSFET 10 is minimized when the threshold voltage of the depletion-type MOSFET 10 is “−0.4 V”. On the other hand, the absolute value of the threshold voltage of the depletion-type MOSFET 10 is maximized when the threshold voltage of the depletion-type MOSFET 10 is “−0.8 V”. A difference between a maximum current value and a minimum current value in a case where the threshold voltage of the depletion-type MOSFET 10 varies between “−0.4 V” and “−0.8 V” is smaller than a difference between a maximum current value and a minimum current value in a case where the threshold voltage of the depletion-type MOSFET 10 varies between “−0.1 V” and “−0.5 V”. As a result, the variation in the start up time of the constant current source can be made smaller in the case where the threshold voltage of the depletion-type MOSFET 10 varies between “−0.4 V” and “−0.8 V” than the case where the threshold voltage of the depletion-type MOSFET 10 varies between “−0.1 V” and “−0.5 V”.

From the above, it is desirable to decrease the threshold voltage of the depletion-type MOSFET 10 from the viewpoint of the decrease in the variation in the start up time of the constant current source.

### Description of First Related Technique

The depletion-type MOSFET used for the constant current source can be made of, for example, an LDMOSFET. A first related technique relating to the LDMOSFET configuring the depletion-type MOSFET will be described below. In this specification, the “first related technique” is not a publicly-known technique but a technique having an issue found by the present inventors as well as a premise technique of the present disclosure.

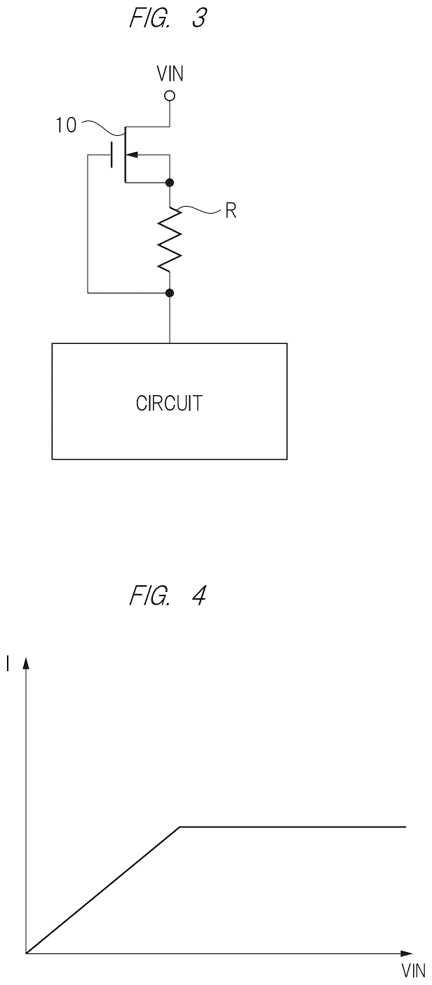

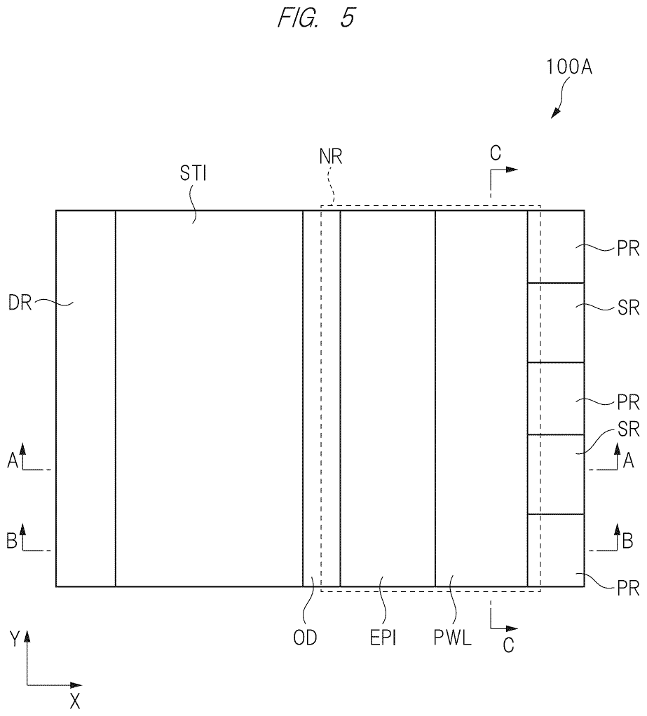

FIG. 5 is a plan view illustrating an LDMOSFET 100A in the first related technique.

In FIG. 5, the LDMOSFET 100A includes a drain region DR, a trench region STI, an offset drain region OD, an epitaxial layer EPI, a p-type well PWL, an n-type semiconductor region NR, a body contact region PR, and a source region SR.

The trench region STI is formed between the drain region DR and the offset drain region OD. The epitaxial layer EPI is formed between the offset drain region OD and the p-type well PWL. The p-type well PWL is formed to be in contact with the epitaxial layer EPI. The body contact region PR and the source region SR are formed in the p-type well PWL. The body contact region PR and the source region SR are alternately arranged in a Y-direction. The n-type semiconductor region NR is in contact with the offset drain region OD, the epitaxial layer EPI, the p-type well PWL, the body contact region PR, and the source region SR. The drain region DR, the trench region STI, the offset drain region OD, the epitaxial layer EPI, the p-type well PWL, the n-type semiconductor region NR, the body contact region PR, and the source region SR are formed as described above.

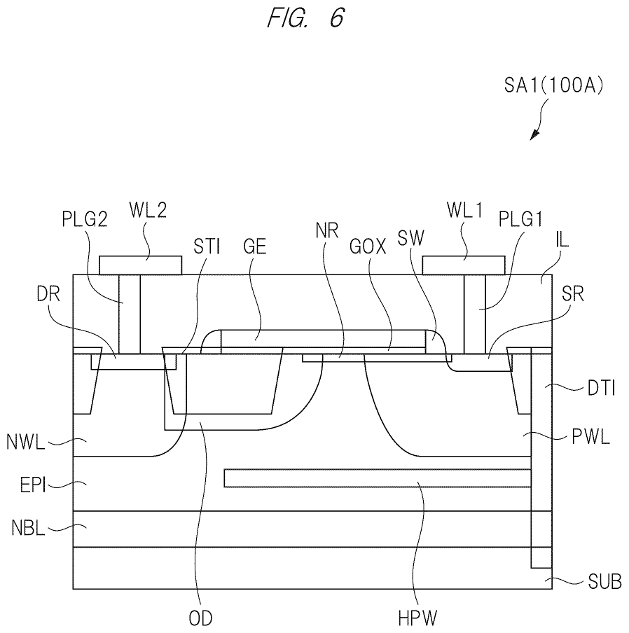

FIG. 6 is a cross-sectional view of the LDMOSFET along a line A-A illustrated in FIG. 5.

FIG. 6 corresponds to a cross-sectional view in a gate length direction of a gate electrode GE. FIG. 6 illustrates a configuration of a semiconductor device SA1 including the LDMOSFET 100A.

In FIG. 6, the semiconductor device SA1 includes a p-type semiconductor substrate SUB, an n-type buried layer NBL, the epitaxial layer EPI, a deep p-type well HPW, the p-type well PWL, an n-type well NWL, the offset drain region OD, the source region SR, the drain region DR, the n-type semiconductor region NR, the trench region STI, a deep trench region DTI, a gate insulating film GOX, the gate electrode GE, a sidewall spacer SW, an interlayer insulating film IL, a plug PLG1, a plug PLG2, a wiring WL1, and a wiring WL2.

The epitaxial layer EPI is formed on the p-type semiconductor substrate SUB. The epitaxial layer EPI is made of a p-type semiconductor layer into which p-type impurities (acceptors) are introduced. The n-type buried layer NBL is formed between the p-type semiconductor substrate SUB and the epitaxial layer EPI. The n-type buried layer NBL is made of an n-type semiconductor layer into which n-type impurities (donors) are introduced. The n-type buried layer NBL may be formed in the p-type semiconductor substrate SUB or the epitaxial layer EPI.

The deep p-type well HPW is formed in the epitaxial layer EPI. The impurity concentration of the deep p-type well HPW is higher than the impurity concentration of the epitaxial layer EPI. The p-type well PWL is formed in the epitaxial layer EPI. The impurity concentration of the p-type well PWL is higher than the impurity concentration of the epitaxial layer EPI. The p-type well PWL is formed over the deep p-type well HPW, and is spaced apart from the deep p-type well HPW. The source region SR is formed in the p-type well PWL. The source region SR is made of an n-type semiconductor region.

Each of the n-type well NWL and the offset drain region OD is formed in the epitaxial layer EPI. The offset drain region OD is made of an n-type semiconductor region. The impurity concentration of the offset drain region OD is lower than the impurity concentration of the n-type well NWL. The offset drain region OD is spaced apart from the p-type well PWL. The offset drain region OD is in contact with the n-type well NWL.

The trench region STI is formed in the offset drain region OD. The trench region STI includes a trench formed in the offset drain region OD and an insulating material filling the trench. The drain region DR is formed in the offset drain regions OD. The drain region DR is made of an n-type semiconductor region. The drain region DR is in contact with the trench region STI. The impurity concentration of the drain region DR is higher than the impurity concentration of the offset drain region OD.

The n-type semiconductor region NR is formed in the epitaxial layer EPI. Specifically, the n-type semiconductor region NR is formed in the offset drain region OD, in the p-type well PWL, and in a portion of the epitaxial layer EPI located between the offset drain region OD and the p-type well PWL. The n-type semiconductor region NR is in contact with the source region SR. On the other hand, the n-type semiconductor region NR is spaced apart from the trench region STI. However, the n-type semiconductor region NR may be in contact with the trench region STI.

The deep trench region DTI penetrates through the epitaxial layer EPI and the n-type buried layer NBL, to reach the p-type semiconductor substrate SUB.

The gate insulating film GOX is formed on the n-type semiconductor region NR. The gate electrode GE is formed on the gate insulating film GOX and the trench region STI. The sidewall spacer SW is formed on a sidewall of the gate electrode GE.

The interlayer insulating film IL is formed on the epitaxial layer EPI, to cover the gate electrode GE. Each of the plug PLG1 and the plug PLG2 penetrates through the interlayer insulating film IL. The plug PLG1 is in contact with the source region SR. Thus, the plug PLG1 is electrically connected to the source region SR. On the other hand, the plug PLG2 is in contact with the drain region DR. Thus, the plug PLG2 is electrically connected to the drain region DR.

Each of the wiring WL1 and the wiring WL2 is formed on the interlayer insulating film IL. The wiring WL1 is connected to the plug PLG1, and is electrically connected to the source region SR via the plug PLG1. The wiring WL2 is connected to the plug PLG2, and is electrically connected to the drain region DR via the plug PLG2. The semiconductor device SA1 including the LDMOSFET 100A illustrated in FIG. 6 is configured as described above.

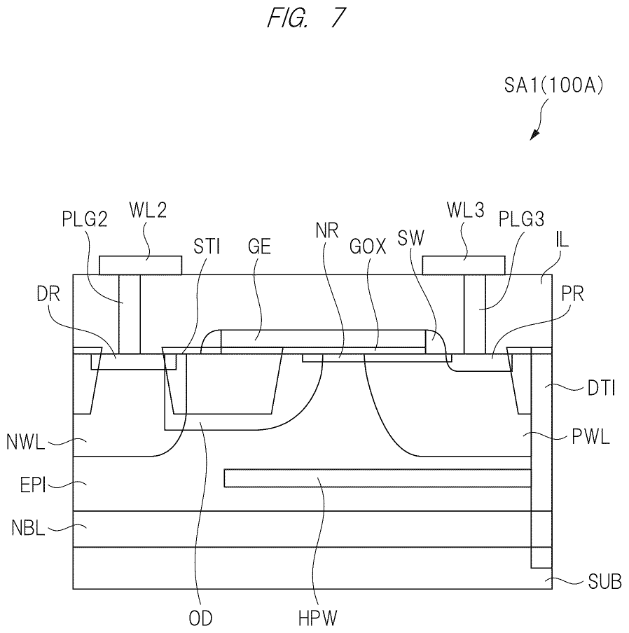

FIG. 7 is a cross-sectional view of the LDMOSFET along a line B-B illustrated in FIG. 5.

FIG. 7 corresponds to a cross-sectional view in the gate length direction of the gate electrode GE. FIG. 7 illustrates a configuration of the semiconductor device SA1 including the LDMOSFET 100A.

The configuration of the semiconductor device SA1 illustrated in FIG. 7 is substantially the same as the configuration of the semiconductor device SA1 illustrated in FIG. 6 except that the body contact region PR is formed instead of the source region SR.

The body contact region PR is made of a p-type semiconductor region. The impurity concentration of the body contact region PR is higher than the impurity concentration of the p-type well PWL. The n-type semiconductor region NR is in contact with the body contact region PR.

A plug PLG3 is formed in the interlayer insulating film IL. The plug PLG3 is in contact with the body contact region PR, and is electrically connected to the body contact region PR. A wiring WL3 is formed on the interlayer insulating film IL. The wiring WL3 is connected to the plug PLG3, and is electrically connected to the body contact region PR via the plug PLG3.

For example, the wiring WL1 illustrated in FIG. 6 and the wiring WL3 illustrated in FIG. 7 are electrically connected to each other. Accordingly, the source region SR and the body contact region PR are electrically connected to each other. That is, the same potential is supplied to the source region SR and the body contact region PR. The semiconductor device SA1 including the LDMOSFET 100A illustrated in FIG. 7 is configured as described above.

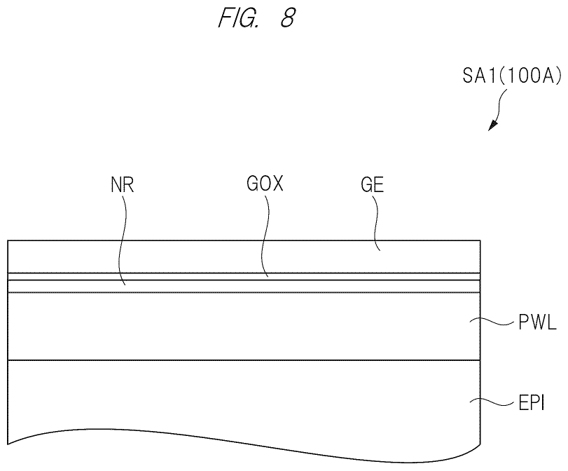

FIG. 8 is a cross-sectional view of the LDMOSFET along a line C-C illustrated in FIG. 5.

FIG. 8 corresponds to a cross-sectional view in the gate width direction of the gate electrode GE. FIG. 8 illustrates a configuration of the semiconductor device SA1 including the LDMOSFET 100A.

As illustrated in FIG. 8, the p-type well PWL is formed on the epitaxial layer EPI. The n-type semiconductor region NR is formed on the p-type well PWL. The gate insulating film GOX is formed on the n-type semiconductor region NR. The gate electrode GE is formed on the gate insulating film GOX. The semiconductor device SA1 including the LDMOSFET 100A illustrated in FIG. 8 is configured as described above.

### Room to be Improved in First Related Technique

In the first related technique, for example, as illustrated in FIG. 5, the threshold voltage of the LDMOSFET 100A can be decreased by forming the n-type semiconductor region NR. The LDMOSFET 100A is an n-channel type MOSFET. In the LDMOSFET 100A, the channel formation region immediately below the gate electrode GE includes an accumulation layer made of the offset drain region OD and the n-type semiconductor region NR. Accordingly, even when 0 V is applied to the gate electrode GE, there is a channel including the accumulation layer and the n-type semiconductor region NR. Therefore, the LDMOSFET 100A is the depletion-type MOSFET having the negative threshold voltage.

Here, when the negative voltage is applied to the gate electrode GE, an electrical repulsive force moves electrons in the n-type semiconductor region NR away from the channel formation region. Thus, when a predetermined negative voltage is applied to the gate electrode GE, the n-type semiconductor region NR configuring a part of the channel is depleted. The depleted n-type semiconductor region NR functions as an insulating region. Accordingly, when a predetermined negative voltage is applied to the gate electrode GE, the channel is difficult to be formed. That is, the LDMOSFET 100A is turned off when a gate voltage lower than its threshold voltage is applied to the gate electrode GE. In this case, the threshold voltage of the LDMOSFET 100A can be controlled by adjusting the impurity concentration of the n-type semiconductor region NR. That is, in the first related technique, the threshold voltage of the LDMOSFET 100A can be decreased by appropriately designing the impurity concentration of the n-type semiconductor region NR. For this reason, in the first related technique, the threshold voltage of the LDMOSFET 100A can be decreased.

In this respect, the n-type semiconductor region NR is formed by introducing n-type impurities into the epitaxial layer EPI and the p-type well PWL. Each of the epitaxial layer EPI and the p-type well PWL is a p-type semiconductor region into which p-type impurities are introduced.

Therefore, in order to form the n-type semiconductor region NR in the epitaxial layer EPI and the p-type well PWL, a dose amount of the n-type impurities to be introduced into the epitaxial layer EPI and the p-type well PWL needs to be increased.

Particularly, in the first related technique, the n-type impurities are introduced into both the epitaxial layer EPI and the p-type well PWL. Here, the p-type impurity concentration of the p-type well PWL is higher than the p-type impurity concentration of the epitaxial layer EPI. Thus, in the first related technique, in order to form the n-type semiconductor region NR, the n-type impurities are also introduced into the p-type well PWL having a higher p-type impurity concentration than that of the epitaxial layer EPI. As a result, the dose amount of the n-type impurities is high.

Here, the n-type impurities to be introduced to form the n-type semiconductor region NR are introduced into not only the epitaxial layer EPI and the p-type well PWL but also the offset drain region OD configuring the accumulation layer. Since the offset drain region OD is the n-type semiconductor region, the introduction of the n-type impurities even into the offset drain region OD increases the n-type impurity concentration of the offset drain region OD. This results in, for example, a portion having a high electric field strength in the offset drain region OD. Thus, the portion having the high electric field strength becomes a hot spot (weak spot), and decreases the breakdown voltage of the LDMOSFET 100A.

The offset drain region OD is formed, thereby improving the breakdown voltage of the LDMOSFET 100A. Specifically, in the LDMOSFET 100A, the offset drain region OD having a lower impurity concentration than the impurity concentration of the drain region DR is formed between the drain region DR and the channel formation region, thereby increasing a distance between the channel formation region and the drain region DR. As a result, according to the LDMOSFET 100A, a sufficient breakdown voltage between the source region SR and the drain region DR can be secured. Further, as illustrated in FIG. 6, in the LDMOSFET 100A, the trench region STI is formed in the offset drain region OD, thereby further increasing the distance between the channel formation region and the drain region DR. As a result, the breakdown voltage between the source region SR and the drain region DR can be further improved. The LDMOSFET 100A is a MOSFET used for applications requiring an appropriate breakdown voltage. Therefore, in the LDMOSFET 100A, it is desirable to avoid the decrease in the breakdown voltage between the source region SR and the drain region DR.

That is, the first related technique can decrease the threshold voltage of the LDMOSFET 100A as the depletion-type MOSFET, but has a risk of the decrease in the breakdown voltage of the LDMOSFET 100A.

### Description of Second Related Technique

Next, a second related technique will be described.

In this specification, the “second related technique” is not a publicly-known technique but a technique having an issue found by the present inventors as well as a premise technique of the present disclosure.

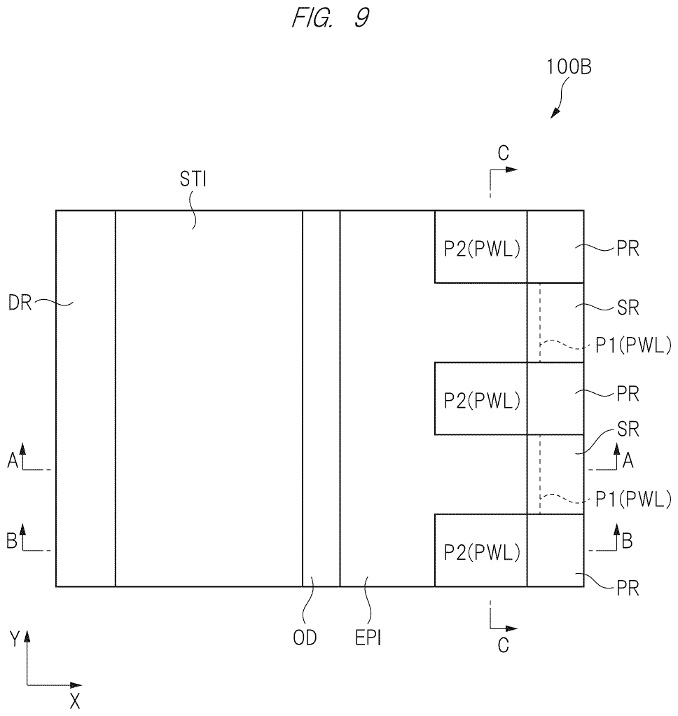

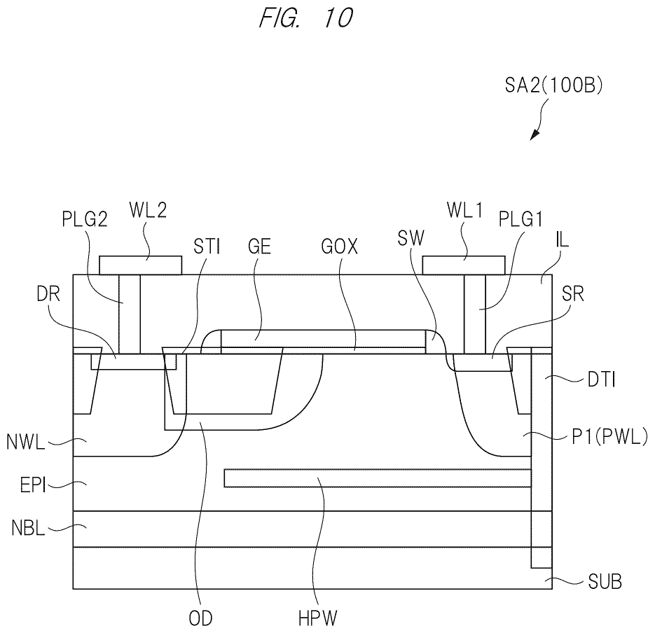

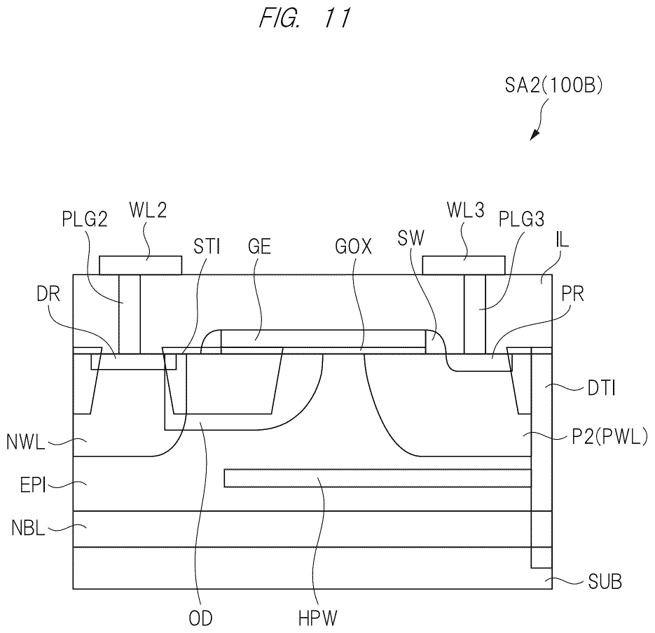

FIG. 9 is a plan view illustrating an LDMOSFET 100B in the second related technique.

In FIG. 9, the LDMOSFET 100B includes the drain region DR, the trench region STI, the offset drain region OD, the epitaxial layer EPI, the p-type well PWL, the body contact region PR, and the source region SR.

The trench region STI is formed between the drain region DR and the offset drain region OD. The offset drain region OD is formed between the trench region STI and the epitaxial layer EPI. The p-type well PWL is formed in the epitaxial layer EPI. Specifically, the p-type well PWL has a first portion P1 and a second portion P2.

In this case, as illustrated in FIG. 9, a first distance between the first portion P1 of the p-type well PWL and the offset drain region OD in an X-direction is larger than a second distance between the second portion P2 of the p-type well PWL and the offset drain region OD in the X-direction. In this specification, such a structure of the p-type well PWL having the first portion P1 and the second portion P2 may be referred to as a “ladder structure”.

In a plan view, the source region SR partially overlaps the first portion P1 of the p-type well PWL. The body contact region PR is formed in the second portion P2 of the p-type well PWL. The body contact region PR and the source region SR are alternately arranged in the Y-direction. The drain region DR, the trench region STI, the offset drain region OD, the epitaxial layer EPI, the p-type well PWL, the body contact region PR, and the source region SR are formed as described above.

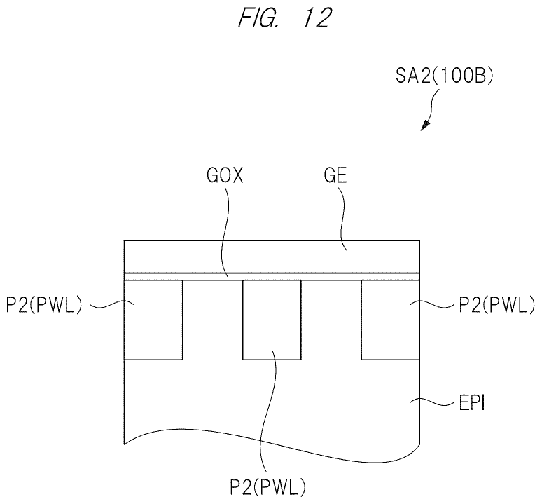

FIG. 10 is a cross-sectional view of the LDMOSFET along a line A-A illustrated in FIG. 9.

FIG. 10 corresponds to a cross-sectional view in the gate length direction of the gate electrode GE. FIG. 10 illustrates a configuration of a semiconductor device SA2 including the LDMOSFET 100B.

In FIG. 10, the semiconductor device SA2 includes the p-type semiconductor substrate SUB, the n-type buried layer NBL, the epitaxial layer EPI, the deep p-type well HPW, the p-type well PWL, the n-type well NWL, the offset drain region OD, the source region SR, the drain region DR, the trench region STI, the deep trench region DTI, the gate insulating film GOX, the gate electrode GE, the sidewall spacer SW, the interlayer insulating film IL, the plug PLG1, the plug PLG2, the wiring WL1, and the wiring WL2.

For example, as illustrated in FIG. 10, in the second related technique, the channel formation region immediately below the gate electrode GE is made of an accumulation layer made of the offset drain region OD and the epitaxial layer EPI. That is, the first portion P1 of the p-type well PWL does not configure the channel formation region. Thus, the first portion P1 of the p-type well PWL is not included in the channel formation region positioned between the source region SR and the offset drain region OD.

FIG. 11 is a cross-sectional view of the LDMOSFET along a line B-B illustrated in FIG. 9.

FIG. 11 corresponds to a cross-sectional view in the gate length direction of the gate electrode GE. FIG. 11 illustrates a configuration of the semiconductor device SA2 including the LDMOSFET 100B.

In FIG. 11, the semiconductor device SA2 includes the p-type semiconductor substrate SUB, the n-type buried layer NBL, the epitaxial layer EPI, the deep p-type well HPW, the p-type well PWL, the n-type well NWL, the offset drain region OD, the body contact region PR, the drain region DR, the trench region STI, the deep trench region DTI, the gate insulating film GOX, the gate electrode GE, the sidewall spacer SW, the interlayer insulating film IL, the plug PLG2, a plug PLG3, the wiring WL2, and a wiring WL3.

As illustrated in FIG. 11, in the second related technique, the p-type well PWL has the “ladder structure”. As a result, the second portion P2 of the p-type well PWL includes a portion positioned between the body contact region PR and the offset drain region OD. That is, the epitaxial layer EPI and a part of the second portion P2 of the p-type well PWL exist between the body contact region PR and the offset drain region OD.

The p-type well PWL has the “ladder structure”. Accordingly, as illustrated in FIG. 10, the first portion P1 of the p-type well PWL does not exist between the source region SR and the offset drain region OD. On the other hand, as illustrated in FIG. 11, the second portion P2 of the p-type well PWL exists between the body contact region PR and the offset drain region OD.

FIG. 12 is a cross-sectional view of the LDMOSFET along a line C-C illustrated in FIG. 9.

FIG. 12 corresponds to a cross-sectional view in the gate width direction of the gate electrode GE. FIG. 12 illustrates a configuration of the semiconductor device SA2 including the LDMOSFET 100B.

As illustrated in FIG. 12, the second portion P2 of the p-type well PWL is formed in the epitaxial layer EPI. Specifically, the second portion P2 of the p-type well PWL are formed with a predetermined interval in the epitaxial layer EPI. The gate insulating film GOX is formed on the epitaxial layer EPI. The gate insulating film GOX is formed on the second portion P2 of the p-type well PWL, but not formed on the first portion P1 of the p-type well PWL. The gate electrode GE is formed on the gate insulating film GOX.

### Room to be Improved in Second Related Technique

The second related technique adopts the p-type well PWL having the “ladder structure”. For example, in FIG. 10, not the p-type well PWL but the epitaxial layer EPI exists between the offset drain region OD and the source region SR. As a result, the threshold voltage of the LDMOSFET 100B can be decreased.

Each of the p-type well PWL and the epitaxial layer EPI is made of a p-type semiconductor region. The impurity concentration of the p-type well PWL is higher than the impurity concentration of the epitaxial layer EPI. Therefore, when not only the epitaxial layer EPI but also the p-type well PWL having a higher impurity concentration than that of the epitaxial layer EPI exists between the offset drain region OD and the source region SR, a gate voltage to be applied to the gate electrode GE to form an inversion layer on a surface of the p-type well PWL is increased. That is, the threshold voltage of the LDMOSFET 100B is increased. In this respect, in the second related technique, not the p-type well PWL but the epitaxial layer EPI having a lower p-type impurity concentration than that of the p-type well PWL exists between the offset drain region OD and the source region SR. As a result, the threshold voltage of the LDMOSFET 100B can be decreased.

However, as different from the first related technique, the second related technique does not include the n-type semiconductor region NR which contributes to the decrease in the threshold voltage of the LDMOSFET 100B. As a result, in the second related technique, the p-type impurity concentration of the epitaxial layer EPI defines the threshold voltage of the LDMOSFET 100B. The decrease in the p-type impurity concentration of the epitaxial layer EPI can decrease the threshold voltage of the LDMOSFET 100B. However, the impurity concentration of the epitaxial layer EPI is lower than the p-type impurity concentration of the other p-type semiconductor region. Accordingly, the decrease in the impurity concentration of the epitaxial layer EPI has limitation. That is, it is more difficult to decrease the threshold voltage of the LDMOSFET 100B in the second related technique than the first related technique. On the other hand, the first related technique has a risk of the decrease in the breakdown voltage of the LDMOSFET 100A.

From the above, in terms of the decrease in the threshold voltage of the LDMOSFET as well as the securement in the sufficient breakdown voltage of the LDMOSFET, there is a room to be improved in each of the first related technique and the second related technique.

Therefore, a technical idea for the decrease in the threshold voltage of the LDMOSFET as well as the securement in the sufficient breakdown voltage of the LDMOSFET will be described.

### Basic Idea

A basic idea is to form the n-type semiconductor region NR in the epitaxial layer EPI between the offset drain region OD and the source region SR in order to decrease the threshold voltage of the LDMOSFET. Further, in the basic idea, the p-type well PWL having a higher p-type impurity concentration than the p-type impurity concentration of the epitaxial layer EPI is not formed between the offset drain region OD and the source region SR.

The p-type well PWL does not exist but the epitaxial layer EPI having a lower p-type impurity concentration than that of the p-type well PWL exists between the offset drain region OD and the source region SR. Accordingly, even if the dose amount of the n-type impurities is not high, the n-type semiconductor region NR can be formed. That is, even if the n-type semiconductor region NR is formed, the dose amount of the n-type impurities to be introduced into the offset drain region OD can be decreased. As a result, according to the basic idea, the electric field concentration due to the n-type impurities to be introduced into the offset drain region OD can be suppressed. Thus, according to the basic idea, the decrease in the breakdown voltage of the LDMOSFET can be suppressed even while the n-type semiconductor region NR is formed to decrease the threshold voltage of the LDMOSFET. That is, the basic idea can achieve the decrease in the threshold voltage of the LDMOSFET as well as the securement of the sufficient breakdown voltage of the LDMOSFET.

A first embodiment in which the basic idea is embodied will be described below.

### First Embodiment

### Configuration of Semiconductor Device

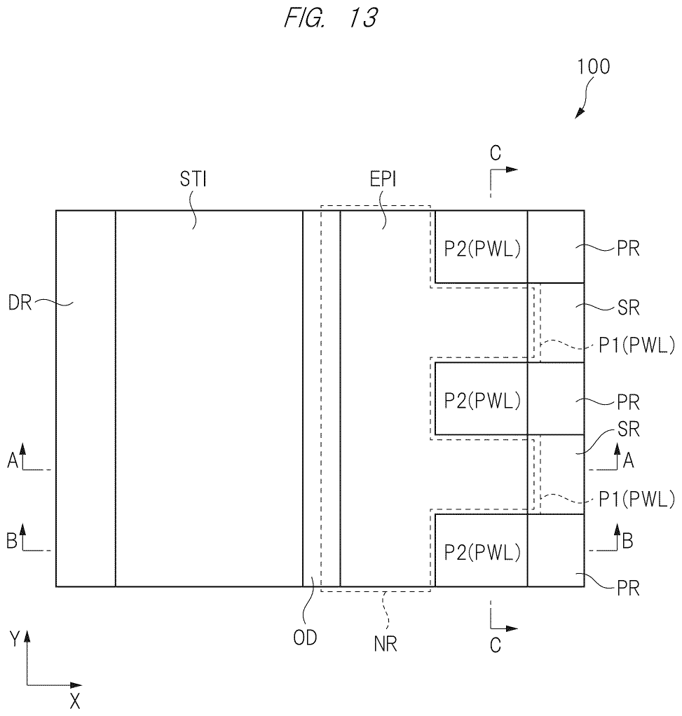

FIG. 13 is a plan view illustrating an LDMOSFET 100 according to a first embodiment.

In FIG. 13, the LDMOSFET 100 includes the drain region DR, the trench region STI, the offset drain region OD, the epitaxial layer EPI, the p-type well PWL, the n-type semiconductor region NR, the body contact region PR, and the source region SR.

The trench region STI is formed between the drain region DR and the offset drain region OD. The offset drain region OD is formed between the trench region STI and the epitaxial layer EPI. The p-type well PWL is formed in the epitaxial layer EPI. Specifically, the p-type well PWL has a first portion P1 and a second portion P2. As illustrated in FIG. 13, a first distance between the first portion P1 of the p-type well PWL and the offset drain region OD in the X-direction is larger than a second distance (a distance in the X-direction) between the second portion P2 of the p-type well PWL and the offset drain region OD in the X-direction. Thus, the p-type well PWL is made of the “ladder structure” having the first portion P1 and the second portion P2. That is, in the “ladder structure” described in this specification, the first distance between the offset drain region OD and the first portion P1 of the p-type well PWL in the gate length direction (X-direction) of the gate electrode GE is larger than the second distance between the offset drain region OD and the second portion P2 of the p-type well PWL in the gate length direction (X-direction) of the gate electrode GE. The first portion P1 of the p-type well PWL and the second portion P2 of the p-type well PWL are adjacent to each other in a gate width direction of the gate electrode GE.

In a plan view, the source region SR is formed to partially overlap the first portion P1 of the p-type well PWL. The body contact region PR is formed in the second portion P2 of the p-type well PWL. The body contact region PR and the source region SR are alternately arranged in the Y-direction. The body contact region PR is in contact with the source region SR. The source region SR and the body contact region PR are adjacent to each other in the gate width direction (Y-direction) of the gate electrode GE.

The drain region DR, the trench region STI, the offset drain region OD, the epitaxial layer EPI, the p-type well PWL, the body contact region PR, and the source region SR are formed as described above.

Further, in the first embodiment, the n-type semiconductor region NR is formed in the epitaxial layer EPI. The n-type semiconductor region NR partially overlaps the offset drain region OD. The n-type semiconductor region NR is in contact with the source regions SR. On the other hand, the n-type semiconductor region NR is not formed in the first portion P1 of the p-type well PWL and the second portion P2 of the p-type well PWL. The drain region DR, the trench region STI, the offset drain region OD, the epitaxial layer EPI, the p-type well PWL, the n-type semiconductor region NR, the body contact region PR, and the source region SR are formed as described above.

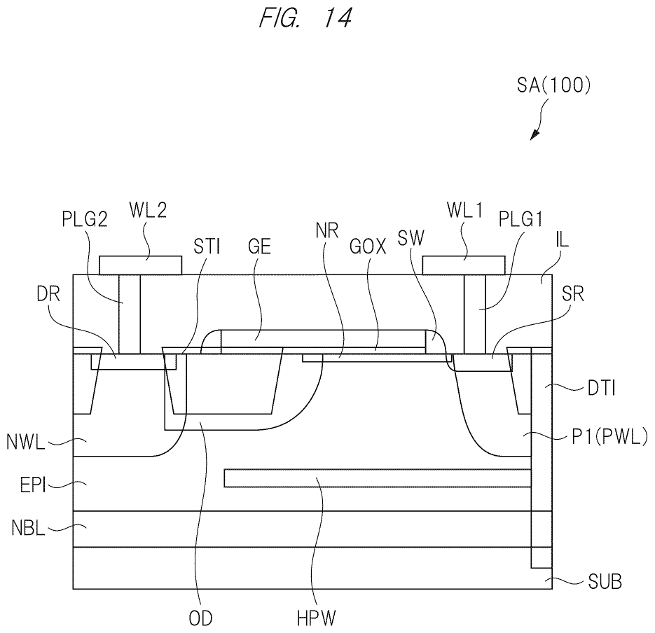

FIG. 14 is a cross-sectional view of the LDMOSFET along a line A-A illustrated in FIG. 13.

FIG. 14 corresponds to a cross-sectional view in the gate length direction of the gate electrode GE. FIG. 14 illustrates a configuration of a semiconductor device SA including the LDMOSFET 100.

In FIG. 14, the semiconductor device SA includes the p-type semiconductor substrate SUB, the n-type buried layer NBL, the epitaxial layer EPI, the deep p-type well HPW, the first portion P1 of the p-type well PWL, the n-type well NWL, the offset drain region OD, the source region SR, the drain region DR, the n-type semiconductor region NR, the trench region STI, the deep trench region DTI, the gate insulating film GOX, the gate electrode GE, the sidewall spacer SW, the interlayer insulating film IL, the plug PLG1, the plug PLG2, the wiring WL1, and the wiring WL2.

The epitaxial layer EPI is formed on the p-type semiconductor substrate SUB. The epitaxial layer EPI is made of a p-type semiconductor layer into which p-type impurities (acceptors) are introduced. The n-type buried layer NBL is formed between the p-type semiconductor substrate SUB and the epitaxial layer EPI. The n-type buried layer NBL is made of an n-type semiconductor layer into which the n-type impurities (donors) are introduced. The n-type buried layer NBL may be formed in the p-type semiconductor substrate SUB or the epitaxial layer EPI.

The deep p-type well HPW is formed in the epitaxial layer EPI. The impurity concentration of the deep p-type well HPW is higher than the impurity concentration of the epitaxial layer EPI. The first portion P1 of the p-type well PWL is formed in the epitaxial layer EPI. The impurity concentration of the first portion P1 of the p-type well PWL is higher than the impurity concentration of the epitaxial layer EPI. The first portion P1 of the p-type well PWL is formed above the deep p-type well HPW, and is spaced apart from the deep p-type well HPW. The source region SR partially overlaps the first portion P1 of the p-type well PWL. The source region SR is made of an n-type semiconductor region. Note that an LDD region may be formed in the source region SR.

As illustrated in FIG. 14, the first portion P1 of the p-type well PWL is arranged not to overlap the gate electrode GE. In other words, the first portion P1 of the p-type well PWL is not formed in the channel formation region positioned under the gate electrode GE.

Each of the n-type well NWL and the offset drain region OD is formed in the epitaxial layer EPI. The offset drain region OD is made of an n-type semiconductor region. The impurity concentration of the offset drain region OD is lower than the impurity concentration of the n-type well NWL. The offset drain region OD is spaced apart from the first portion P1 of the p-type well PWL. The offset drain region OD is in contact with the n-type well NWL.

The trench region STI is formed in the offset drain region OD. The trench region STI includes the trench formed in the offset drain region OD and the insulating material filling the trench. The drain region DR is formed in the offset drain region OD. The drain region DR is made of an n-type semiconductor region. The drain region DR is in contact with the trench region STI. The impurity concentration of the drain region DR is higher than the impurity concentration of the offset drain region OD.

The n-type semiconductor region NR is formed in the epitaxial layer EPI. Specifically, the n-type semiconductor region NR is formed in the offset drain region OD and in a portion of the epitaxial layer EPI located between the offset drain region OD and the source region SR. The n-type semiconductor region NR is in contact with the source region SR. On the other hand, the n-type semiconductor region NR is spaced apart from the trench region STI. However, the n-type semiconductor region NR may be in contact with the trench region STI.

Thus, in the first embodiment, the channel formation region positioned under the gate electrode GE includes an accumulation layer made of the offset drain region OD and the n-type semiconductor region NR formed in the epitaxial layer EPI. The n-type semiconductor region NR is arranged not to be formed in the first portion P1 of the p-type well PWL.

The deep trench region DTI penetrates through the epitaxial layer EPI and the n-type buried layer NBL, to reach the p-type semiconductor substrate SUB.

The gate insulating film GOX is formed on the n-type semiconductor region NR. The gate electrode GE is formed on the gate insulating film GOX and the trench region STI. The sidewall spacer SW is formed on a sidewall of the gate electrode GE. The channel formation region is positioned under the gate electrode GE. The channel formation region is made of the accumulation layer made of the offset drain region OD and the n-type semiconductor region NR.

The interlayer insulating film IL is formed on the epitaxial layer EPI, to cover the gate electrode GE. Each of the plug PLG1 and the plug PLG2 penetrates through the interlayer insulating film IL. The plug PLG1 is in contact with the source region SR. Thus, the plug PLG1 is electrically connected to the source region SR. On the other hand, the plug PLG2 is in contact with the drain region DR. Thus, the plug PLG2 is electrically connected to the drain region DR.

Each of the wiring WL1 and the wiring WL2 is formed on the interlayer insulating film IL. The wiring WL1 is connected to the plug PLG1, and is electrically connected to the source region SR via the plug PLG1. The wiring WL2 is connected to the plug PLG2, and is electrically connected to the drain region DR via the plug PLG2. The semiconductor device SA including the LDMOSFET 100 illustrated in FIG. 14 is configured as described above.

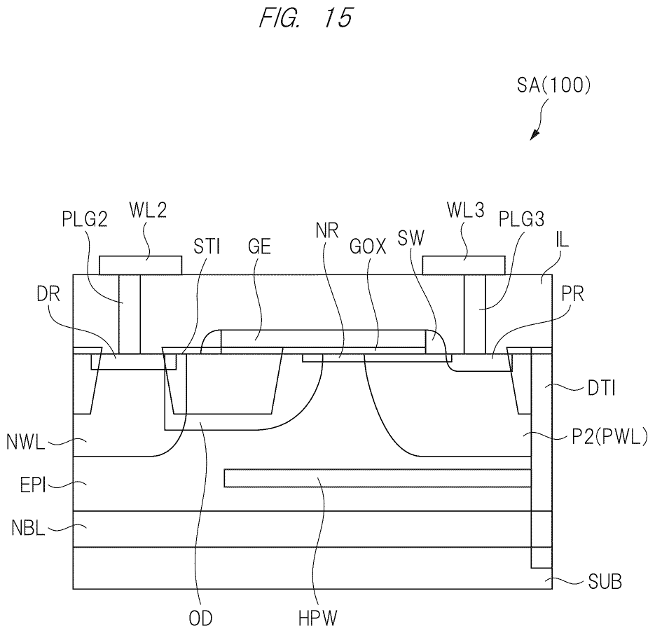

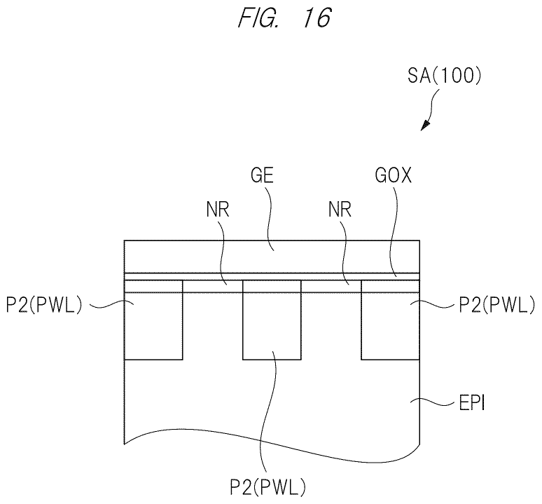

FIG. 15 is a cross-sectional view of the LDMOSFET along a line B-B illustrated in FIG. 13.

FIG. 15 corresponds to a cross-sectional view in the gate length direction of the gate electrode GE. FIG. 15 illustrates a configuration of the semiconductor device SA including the LDMOSFET 100. The configuration of the semiconductor device SA illustrated in FIG. 15 is substantially the same as the configuration of the semiconductor device SA illustrated in FIG. 14 except that the body contact region PR is formed instead of the source region SR.

The body contact region PR is made of a p-type semiconductor region. The impurity concentration of the body contact region PR is higher than the impurity concentration of the p-type well PWL.

The second portion P2 of the p-type well PWL includes the body contact region PR. The second portion P2 of the p-type well PWL partially overlaps the gate electrode GE.

The n-type semiconductor region NR is included in the epitaxial layer EPI. Specifically, the n-type semiconductor region NR is formed in the offset drain region OD and in a portion of the epitaxial layer EPI located between the offset drain region OD and the second portion P2 of the p-type well PWL. The n-type semiconductor region NR is in contact with the second portion P2 of the p-type well PWL. However, the n-type semiconductor region NR is arranged not to be formed in the second portion P2 of the p-type well PWL. As a result, the n-type semiconductor region NR is spaced apart from the body contact region PR formed in the second portion P2 of the p-type well PWL.

The plug PLG3 is formed in the interlayer insulating film IL. The plug PLG3 is in contact with the body contact region PR, and is electrically connected to the body contact region PR. The wiring WL3 is formed on the interlayer insulating film IL. The wiring WL3 is connected to the plug PLG3, and is electrically connected to the body contact region PR via the plug PLG3.

For example, the wiring WL1 illustrated in FIG. 14 and the wiring WL3 illustrated in FIG. 15 are electrically connected to each other. Accordingly, the source region SR and the body contact region PR are electrically connected to each other. That is, the same potential is supplied to the source region SR and the body contact region PR. The semiconductor device SA including the LDMOSFET 100 illustrated in FIG. 15 is configured as described above.

FIG. 16 is a cross-sectional view of the LDMOSFET along a line C-C illustrated in FIG. 13.

FIG. 16 corresponds to a cross-sectional view in the gate width direction of the gate electrode GE. FIG. 16 illustrates a configuration of the semiconductor device SA including the LDMOSFET 100.

As illustrated in FIG. 16, the second portion P2 of the p-type well PWL is formed in the epitaxial layer EPI. Specifically, the second portion P2 of the p-type well PWL are formed with a predetermined interval in the epitaxial layer EPI. The n-type semiconductor region NR is formed in a portion of the epitaxial layer EPI between the second portions P2 of the p-type well PWL adjacent to each other. The gate insulating film GOX is formed on the epitaxial layer EPI. Specifically, the gate insulating film GOX is formed on the second portion P2 of the p-type well PWL and on the n-type semiconductor region NR. The gate electrode GE is formed on the gate insulating film GOX.

The semiconductor device SA according to the first embodiment is configured as described above.

### Modification Example

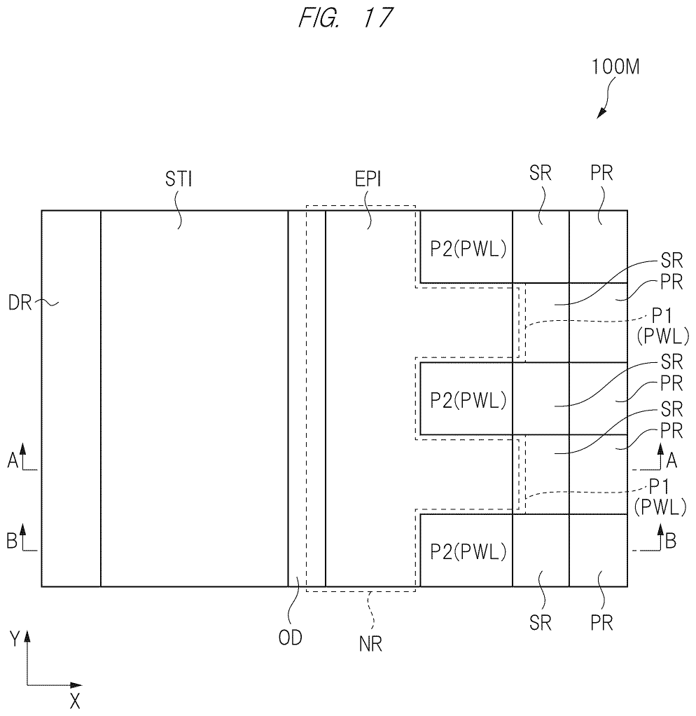

FIG. 17 is a plan view illustrating an LDMOSFET 100M according to a modification example to the first embodiment. In FIG. 17, the LDMOSFET 100M includes the drain region DR, the trench region STI, the offset drain region OD, the epitaxial layer EPI, the p-type well PWL, the n-type semiconductor region NR, the body contact region PR, and the source region SR.

In the above-described first embodiment, as illustrated in FIG. 13, the source region SR and the body contact region PR are adjacent to each other in the Y-direction. That is, the source region SR and the body contact region PR are adjacent to each other in the gate width direction of the gate electrode GE.

On the other hand, in the modification example, as illustrated in FIG. 17, the source region SR and the body contact region PR are adjacent to each other in the X-direction. That is, the source region SR and the body contact region PR are adjacent to each other in the gate length direction of the gate electrode GE.

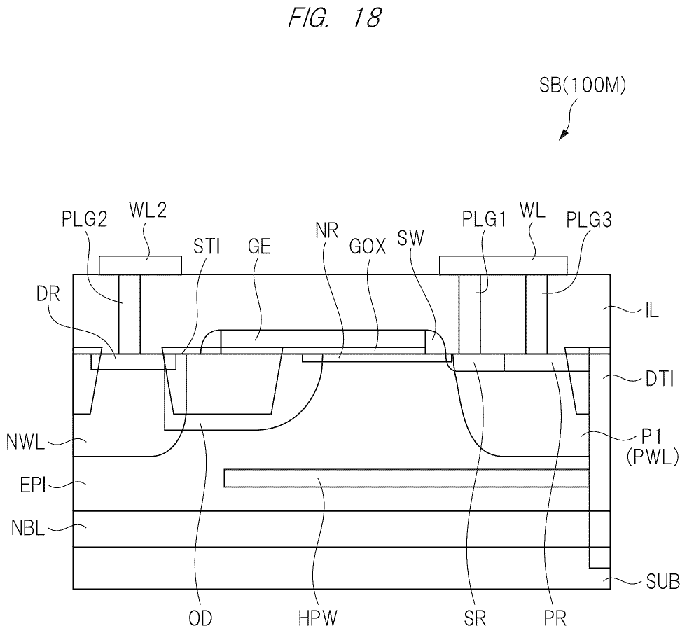

FIG. 18 is a cross-sectional view of the LDMOSFET along a line A-A illustrated in FIG. 17.

FIG. 18 corresponds to a cross-sectional view in the gate length direction of the gate electrode GE. FIG. 18 illustrates a configuration of a semiconductor device SB including the LDMOSFET 100M.

In FIG. 18, the semiconductor device SB includes the p-type semiconductor substrate SUB, the n-type buried layer NBL, the epitaxial layer EPI, the deep p-type well HPW, a first portion P1 of the p-type well PWL, the n-type well NWL, the offset drain region OD, the source region SR, the drain region DR, the n-type semiconductor region NR, the trench region STI, the deep trench region DTI, the gate insulating film GOX, the gate electrode GE, the sidewall spacer SW, the interlayer insulating film IL, the plug PLG1, the plug PLG2, the plug PLG3, the wiring WL, and the wiring WL2.

In FIG. 18, the source region SR is formed in the epitaxial layer EPI to partially overlap the first portion P1 of the p-type well PWL. On the other hand, the body contact region PR is formed in the first portion P1 of the p-type well PWL. The source region SR and the body contact region PR are in contact with each other.

The source region SR is connected to the plug PLG1. The body contact region PR is connected to the plug PLG3. Each of the plug PLG1 and the plug PLG3 is electrically connected to the wiring WL. As a result, the source region SR and the body contact region PR are electrically connected to each other. Accordingly, the same potential is supplied to the source region SR and the body contact region PR.

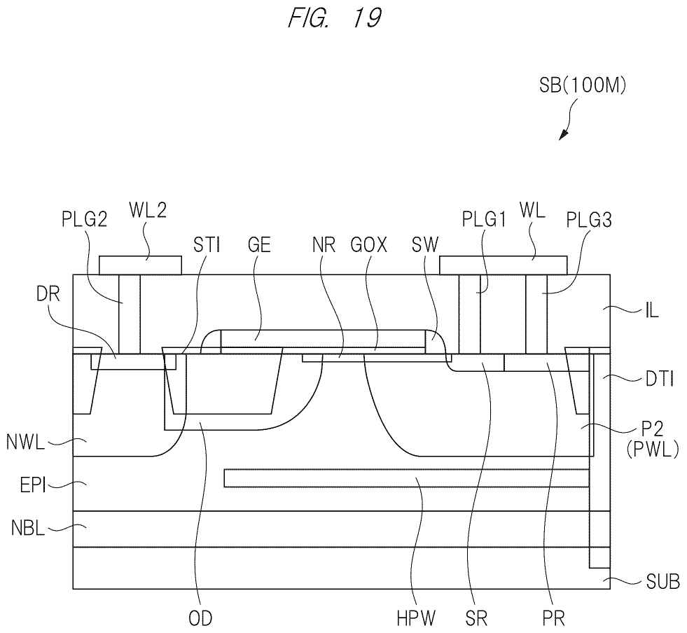

FIG. 19 is a cross-sectional view of the LDMOSFET along a line B-B illustrated in FIG. 17.

FIG. 19 corresponds to a cross-sectional view in the gate length direction of the gate electrode GE. FIG. 19 illustrates a configuration of the semiconductor device SB including the LDMOSFET 100M.

In FIG. 19, the source region SR and the body contact region PR are formed in a second portion P2 of the p-type well PWL. The source region SR and the body contact region PR are in contact with each other.

The source region SR is connected to the plug PLG1. The body contact region PR is connected to the plug PLG3. Each of the plug PLG1 and the plug PLG3 is electrically connected to the wiring WL. As a result, the source region SR and the body contact region PR are electrically connected to each other. Accordingly, the same potential is supplied to the source region SR and the body contact region PR.

The basic idea is also applicable to not only the semiconductor device SA described in the first embodiment but also the semiconductor device SB described in the modification example.

### Method of Manufacturing Semiconductor Device

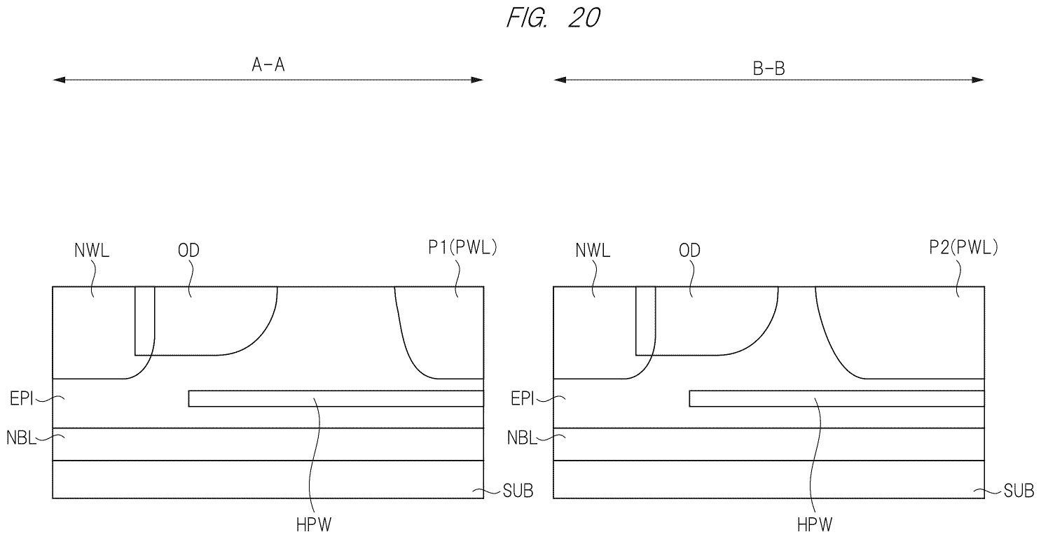

Next, a method of manufacturing the semiconductor device SA according to the first embodiment will be described with reference to FIGS. 20 to 25. FIGS. 20 to 25 are diagrams illustrating steps of manufacturing the semiconductor device SA, and illustrate cross-sectional views corresponding to the cross section A-A or the cross section B-B illustrated in FIG. 13, respectively.

As illustrated in FIG. 20, the n-type buried layer NBL, the deep p-type well HPW, the first portion P1 of the p-type well PWL, the second portion P2 of the p-type well PWL, the n-type well NWL, and the offset drain region OD are formed in the epitaxial layer EPI formed on the p-type semiconductor substrate SUB by using a general semiconductor manufacturing technique. Note that the n-type buried layer NBL may be formed in not the epitaxial layer EPI but the p-type semiconductor substrate SUB.

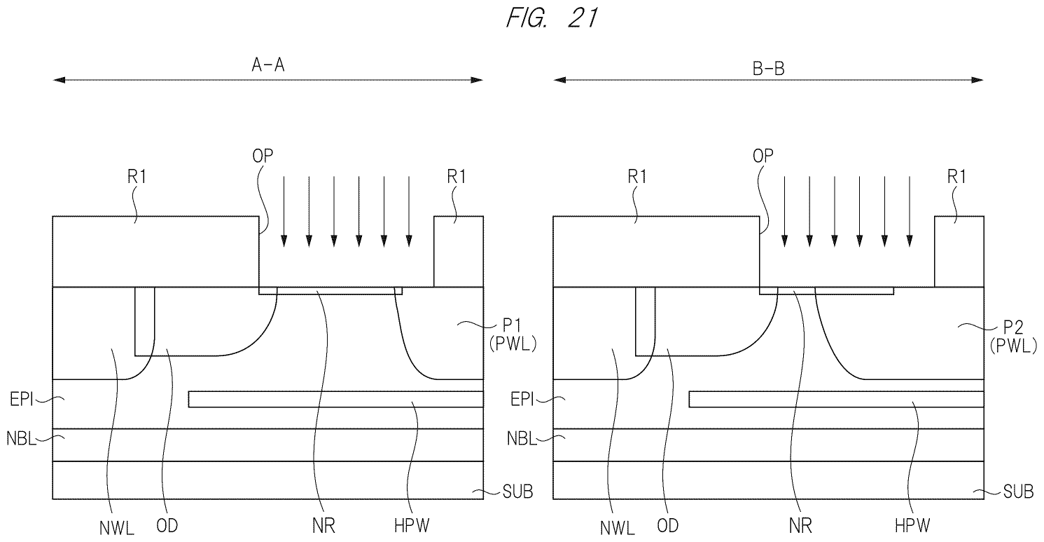

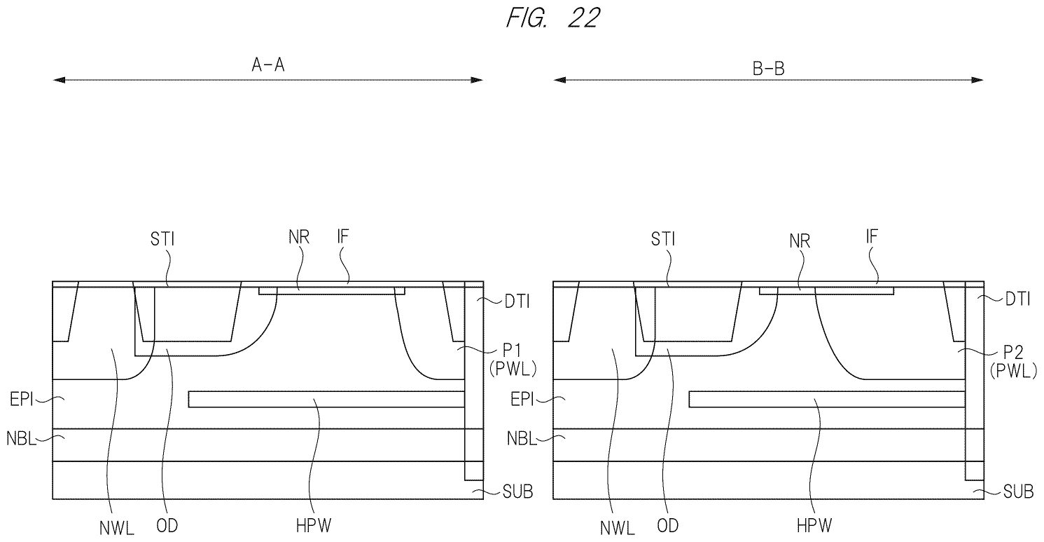

Then, as illustrated in FIG. 21, a resist film R1 is applied onto the epitaxial layer EPI. Then, the resist film R1 is patterned by using a photolithography technique, thereby forming an opening OP in the resist film R1. Then, the n-type impurities (donors) such as phosphorus (P) or arsenic (As) are introduced into the epitaxial layer EPI exposed from the opening OP by an ion implantation method using the patterned resist film R1 as a mask. Specifically, in the cross section A-A, the n-type impurities are introduced into a part of the offset drain region OD, a portion of the epitaxial layer EPI between the offset drain region OD and the first portion P1 of the p-type well PWL, and a part of the first portion P1 of the p-type well PWL.

In the cross section B-B, the n-type impurities are introduced into a part of the offset drain region OD, a portion of the epitaxial layer EPI located between the offset drain region OD and the second portion P2 of the p-type well PWL, and a part of the second portion P2 of the p-type well PWL. Thus, in the cross section A-A, the n-type semiconductor region NR is formed in the part of the offset drain region OD and in the portion of the epitaxial layer EPI located between the offset drain region OD and the first portion P1 of the p-type well PWL. In the cross section B-B, the n-type semiconductor region NR is formed in the part of the offset drain region OD and in the portion of the epitaxial layer EPI located between the offset drain region OD and the second portion P2 of the p-type well PWL.

Note that the n-type impurities are also introduced into the part of the first portion P1 of the p-type well PWL and the part of the second portion P2 of the p-type well PWL. However, the amount of the p-type impurities included in the p-type well PWL is larger than the dose amount of the n-type impurities. Accordingly, the n-type semiconductor region NR is not formed in the part of the first portion P1 of the p-type well PWL and the part of the second portion P2 of the p-type well PWL. On the other hand, the amount of p-type impurities included in the epitaxial layer EPI is smaller than the dose amount of the n-type impurities to be introduced. Accordingly, the n-type semiconductor region NR is formed in the epitaxial layer EPI. That is, the n-type impurities are introduced such that the n-type semiconductor region NR is formed in the epitaxial layer EPI, while the n-type semiconductor region NR is not formed in the p-type well PWL.

Then, as illustrated in FIG. 22, the deep trench region DTI and the trench region STI are formed. The deep trench region DTI is formed by forming a trench that penetrates through the p-type well PWL, the deep p-type well HPW, and the n-type buried layer NBL from an upper surface of the epitaxial layer EPI to reach the p-type semiconductor substrate SUB and then filling the trench with the insulating material. The trench region STI is formed by forming a trench in the offset drain region OD and then filling the trench with the insulating material. Then, the insulating film IF is formed on the upper surface of the epitaxial layer EPI by, for example, a thermal oxidation method. The insulating film IF is made of, for example, a silicon oxide film.

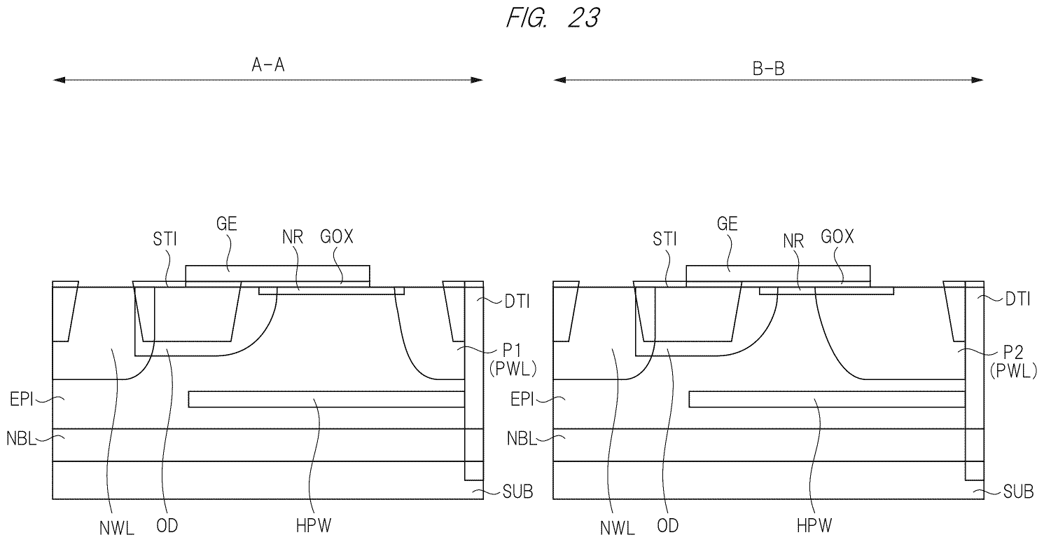

Then, a polysilicon film is formed on the insulating film IF. Then, the polysilicon film is patterned by using a photolithography technique and an etching technique. Thus, as illustrated in FIG. 23, the gate electrode GE is formed. Then, the insulating film IF is patterned while using the gate electrode GE as a mask, thereby forming the gate insulating film GOX. Then, although not illustrated, the n-type impurities are introduced into the epitaxial layer EPI by an ion implantation method using the gate electrode GE as a mask. Thus, the LDD region is formed. Note that the LDD region may not be formed.

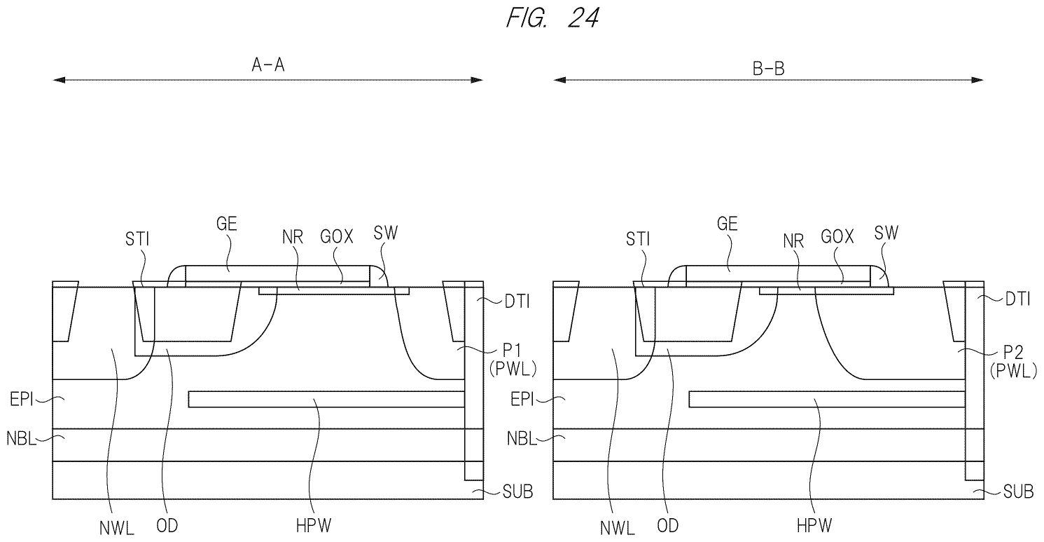

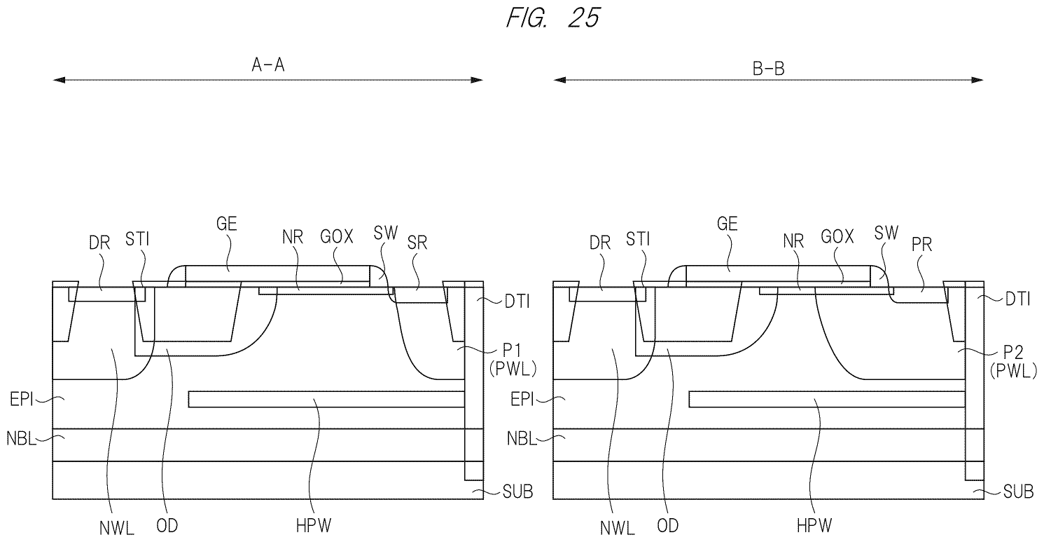

Then, as illustrated in FIG. 24, the sidewall spacer SW is formed on a sidewall of the gate electrode GE. Then, as illustrated in FIG. 25, the drain region DR and the source region SR in the cross section A-A are formed by using a photolithography technique and an ion implantation method. The body contact region PR in the cross section B-B is formed by using a photolithography technique and an ion implantation method.

Then, although not illustrated, the interlayer insulating film and the wiring are formed by using a general semiconductor manufacturing technique. The semiconductor device SA can be manufactured as described above.

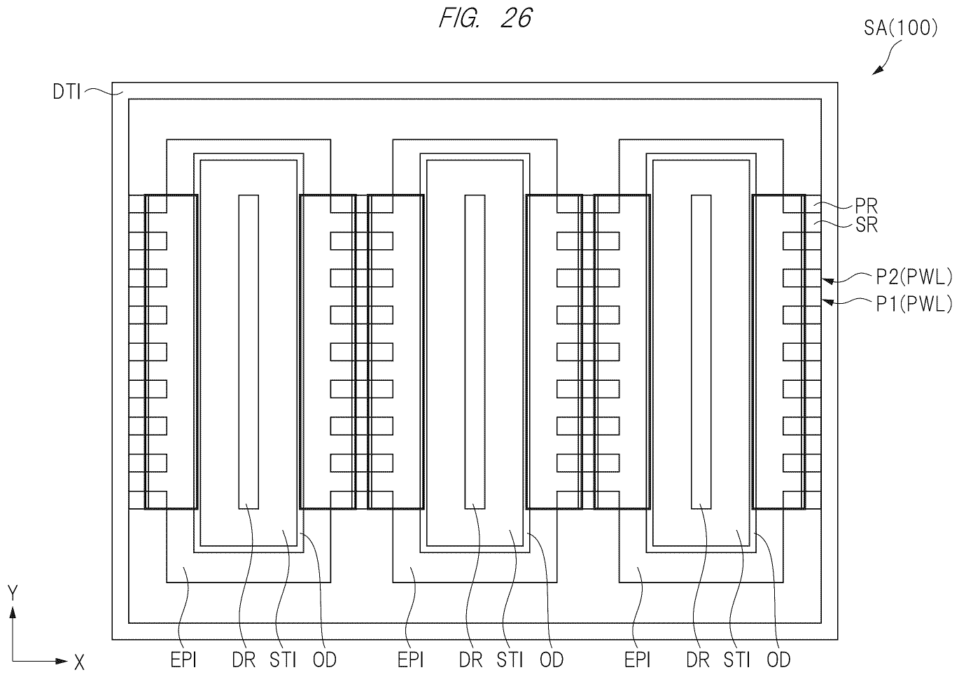

For example, in the first embodiment, as illustrated in FIG. 21, in order to form the n-type semiconductor region NR, the n-type impurities such as phosphorus (P) or arsenic (As) are introduced by an ion implantation method using the patterned resist film R1 as a mask. At this time, a mask having an opening surrounded by a thick line illustrated in each of the following FIGS. 26 to 28 can be used.

By the opening illustrated in FIG. 26, a region where the n-type impurities for forming the n-type semiconductor region NR are introduced is exposed out. Thus, the n-type impurities are not introduced into a region where the n-type impurities do not need to be introduced. As a result, the use of the mask illustrated in FIG. 26 can suppress a variation in the property of the LDMOSFET 100 due to the introduction of the n-type impurities into the region where the n-type impurities do need not to be introduced.

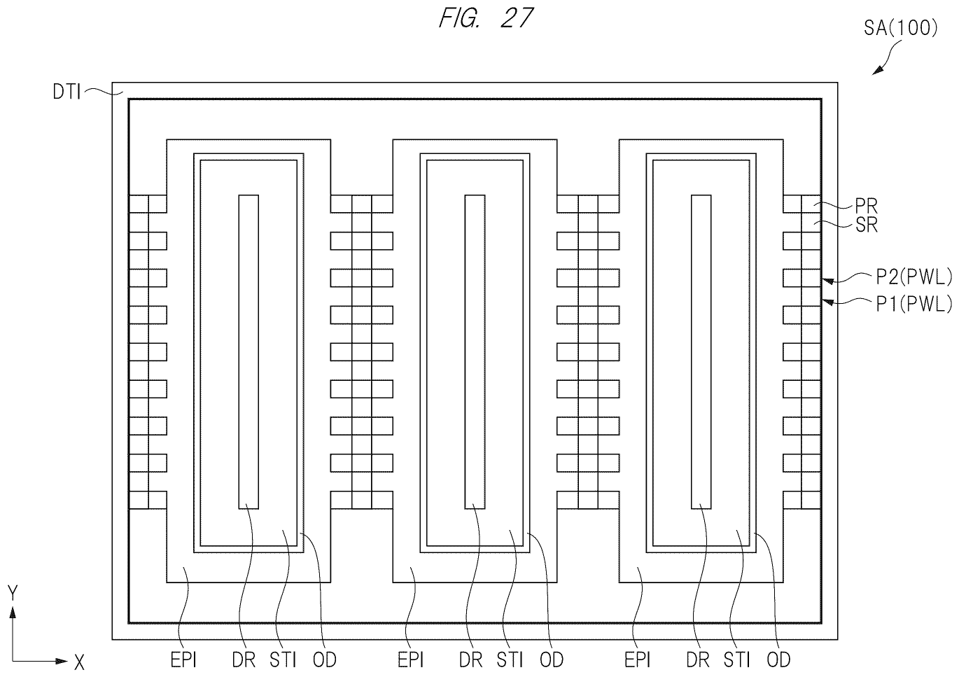

The opening illustrated in FIG. 27 opens a region surrounded by the deep trench region DTI. As a result, a variation in the formation of the n-type semiconductor region NR due to mask misalignment is suppressed. Therefore, the variation in the property of the LDMOSFET 100 due to the variation in the formation of the n-type semiconductor region NR can be suppressed.

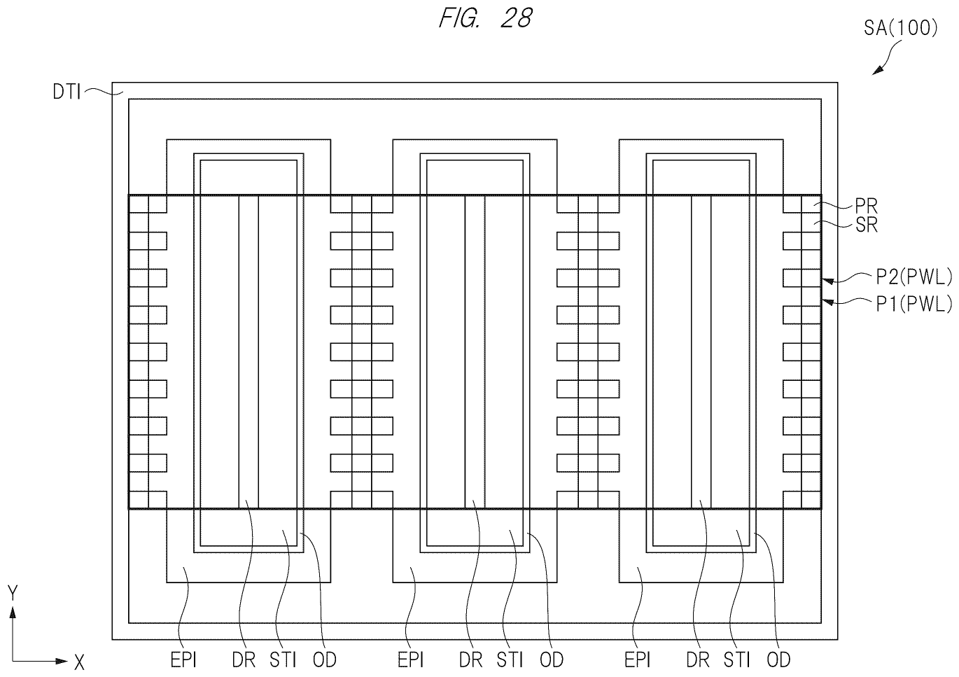

The opening illustrated in FIG. 28 is larger than the opening illustrated in FIG. 26 and smaller than the opening illustrated in FIG. 27. The n-type impurities are not introduced into vicinity of an end of the LDMOSFET 100 in the gate width direction (Y-direction). Particularly, when the mask having the opening illustrated in FIG. 28 is used, the n-type impurities are not introduced into a corner of the epitaxial layer EPI where the breakdown voltage of the LDMOSFET 100 easily decreases, in a region surrounded by the deep trench region DTI. Therefore, the use of the mask having the opening illustrated in FIG. 28 can suppress the variation in the property of the LDMOSFET 100 due to the mask misalignment in the gate length direction and the decrease in the breakdown voltage of the LDMOSFET 100 due to the introduction of the n-type impurities into the vicinity of the end of the epitaxial layer EPI in the gate width direction.

### Features in First Embodiment

Features in the first embodiment are as follows.

For example, as illustrated in FIG. 13, the p-type well PWL is made of the “ladder structure” having the first portion P1 and the second portion P2.

For example, as illustrated in FIG. 14, the n-type semiconductor region NR is formed in the portion of the epitaxial layer EPI between the offset drain region OD and the source region SR.

Thus, the p-type well PWL is arranged not to be formed between the offset drain region OD and the source region SR. That is, not the p-type well PWL but the epitaxial layer EPI exists between the offset drain region OD and the source region SR. The p-type well PWL having a higher p-type impurity concentration than that of the epitaxial layer EPI is not formed between the offset drain region OD and the source region SR forming the n-type semiconductor region NR. Therefore, in the first embodiment, when the n-type semiconductor region NR is formed between the offset drain region OD and the source region SR, the n-type semiconductor region NR can be formed without increasing the dose amount of the n-type impurities.

That is, in the first embodiment, not the p-type well PWL but the epitaxial layer EPI having a lower p-type impurity concentration than that of the p-type well PWL exists between the offset drain region OD and the source region SR. Accordingly, the n-type semiconductor region NR can be formed without increasing the dose amount of the n-type impurities.

That is, in order to form the n-type semiconductor region NR, it is necessary to introduce the n-type impurities for canceling the p-type impurities which have already been introduced into the p-type semiconductor region. Therefore, in order to form the n-type semiconductor region NR in the p-type well PWL having a higher p-type impurity concentration than that of the epitaxial layer EPI, the dose amount of the n-type impurities needs to be larger than that in the case of the formation of the n-type semiconductor region NR in the epitaxial layer EPI having a lower p-type impurity concentration than that of the p-type well PWL. In this respect, according to the first embodiment, not the p-type well PWL but the epitaxial layer EPI exists between the offset drain region OD and the source region SR. Accordingly, the n-type semiconductor region NR can be formed without increasing the dose amount of the n-type impurities. That is, even if the n-type semiconductor region NR is formed, the dose amount of the n-type impurities to be introduced into the offset drain region OD can be decreased. Therefore, according to the first embodiment, the electric field concentration due to the n-type impurities to be introduced into the offset drain region OD can be suppressed. Therefore, according to the first embodiment, the decrease in the breakdown voltage of the LDMOSFET 100 can be suppressed while the n-type semiconductor region NR is formed to decrease the threshold voltage of the LDMOSFET 100.

### Second Embodiment

Next, a second embodiment will be described.

A configuration in the second embodiment is substantially the same as the above-described configuration in the first embodiment except for a configuration of the n-type semiconductor region NR. Accordingly, a difference between the second embodiment and the first embodiment will be mainly described.

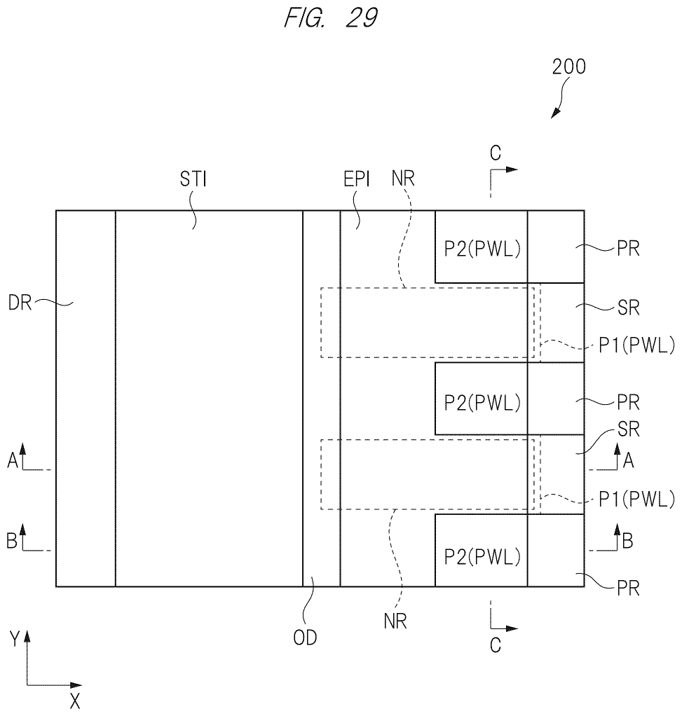

FIG. 29 is a plan view illustrating an LDMOSFET 200 according to the second embodiment.

In FIG. 29, in the second embodiment, the n-type semiconductor region NR is formed in a portion of the epitaxial layer EPI. For example, as illustrated in FIG. 29, the n-type semiconductor region NR is formed in a portion of the epitaxial layer EPI in the X-direction located between the offset drain region OD and the source region SR. On the other hand, as illustrated in FIG. 29, the n-type semiconductor region NR is not formed in a portion of the epitaxial layer EPI in the X-direction between the offset drain region OD and the second portion P2 of the p-type well PWL.

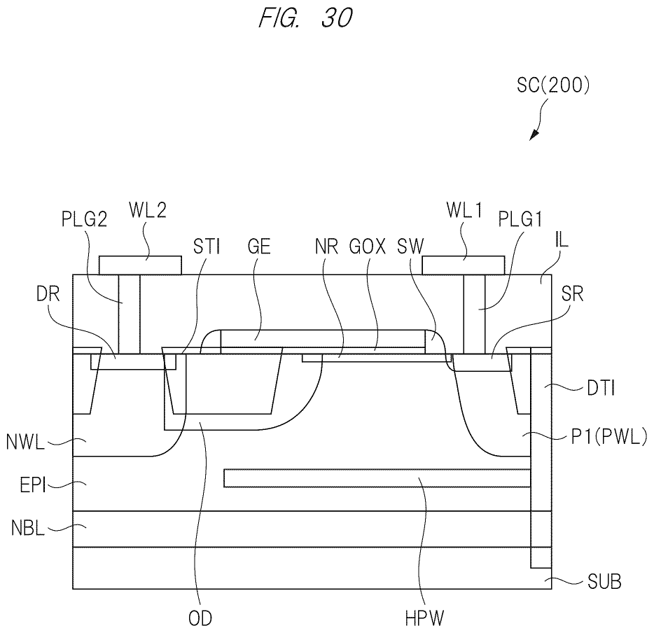

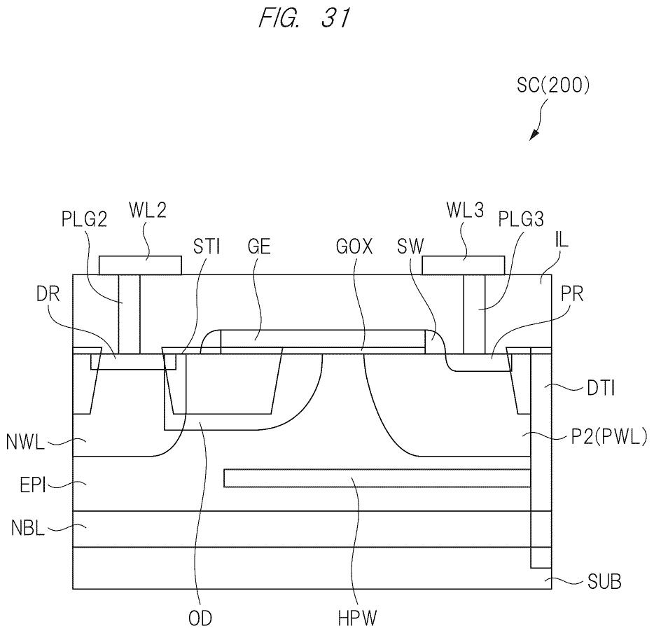

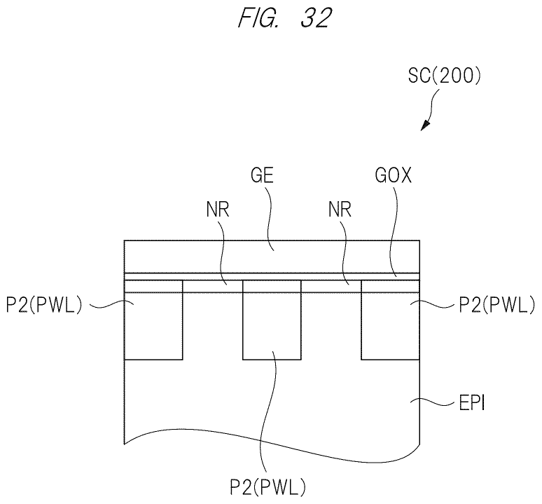

FIG. 30 is a cross-sectional view of the LDMOSFET 200 along a line A-A illustrated in FIG. 29. FIG. 30 is similar to FIG. 14. Accordingly, description of FIG. 30 is omitted. FIG. 31 is a cross-sectional view of the LDMOSFET 200 along a line B-B illustrated in FIG. 29. As illustrated in FIG. 31, the n-type semiconductor region NR is not formed in the portion of the epitaxial layer EPI in the X-direction located between the offset drain region OD and the second portion P2 of the p-type well PWL. FIG. 32 is a cross-sectional view of the LDMOSFET 200 along a line C-C illustrated in FIG. 29. As illustrated in FIG. 32, the n-type semiconductor region NR is formed in a portion of the epitaxial layer EPI located between the second portions P2 of the p-type well PWL spaced apart at a predetermined interval. The semiconductor device SC in the second embodiment is configured as described above.

### Features in Second Embodiment

In the second embodiment, the n-type semiconductor region NR is also formed in the portion of the epitaxial layer EPI located between the offset drain region OD and the source region SR. That is, the n-type semiconductor region NR is formed in the channel formation region located under the gate electrode GE. Therefore, the threshold voltage of the LDMOSFET 200 can be decreased. Particularly, in the second embodiment, the p-type well PWL is also made of the “ladder structure” having the first portion P1 and the second portion P2. Therefore, the p-type well PWL having a higher p-type impurity concentration than the p-type impurity concentration of the epitaxial layer EPI is not formed between the offset drain region OD and the source region SR. Accordingly, the n-type semiconductor region NR can be formed without increasing the dose amount of the n-type impurities. Therefore, the increase in the n-type impurity concentration of the offset drain region OD can be suppressed. Even in the second embodiment, the threshold voltage of the LDMOSFET 200 can be decreased while the sufficient breakdown voltage of the LDMOSFET 200 is secured.

On the other hand, in the second embodiment, the n-type semiconductor region NR is not formed in the portion of the epitaxial layer EPI located between the offset drain region OD and the second portion P2 of the p-type well PWL. As a result, in the second embodiment, the formation of the weak spot that contributes to the decrease in the breakdown voltage of the LDMOSFET 200 is suppressed by the introduction of the n-type impurities. That is, in the second embodiment, the n-type semiconductor region NR is formed in a region that contributes to the decrease in the threshold voltage of the LDMOSFET 200, while the n-type semiconductor region NR is not formed in a region that does not easily contribute to the decrease in the threshold voltage of the LDMOSFET 200. Therefore, the second embodiment does not cause the decrease in the breakdown voltage of the LDMOSFET 200 due to the introduction of the n-type impurities into the unnecessary region. That is, in the second embodiment, the threshold voltage of the LDMOSFET 200 can be decreased without generating the weak spot that is a cause of the decrease in the breakdown voltage of the LDMOSFET 200.

### Third Embodiment

Next, a third embodiment will be described.

A configuration in the third embodiment is substantially the same as the above-described configuration in the first embodiment except for the n-type semiconductor region NR. Accordingly, a difference between the third embodiment and the first embodiment will be mainly described.

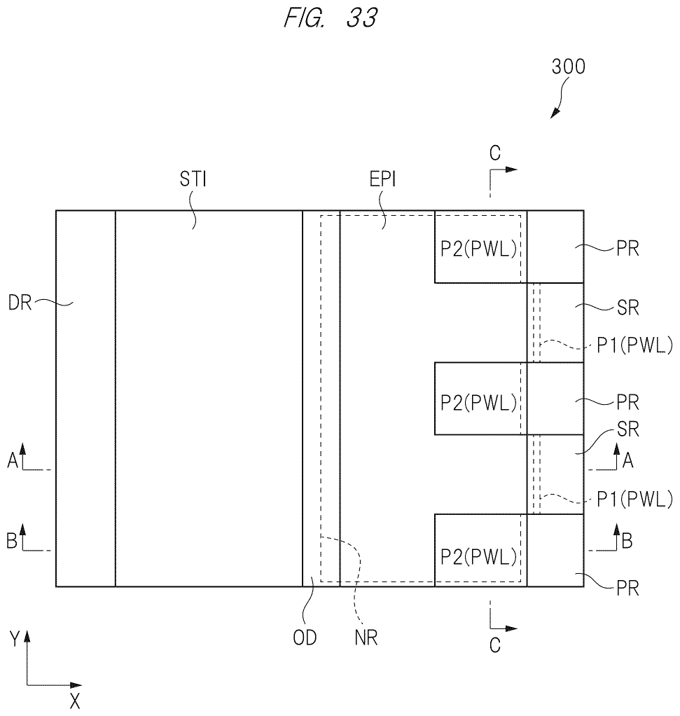

FIG. 33 is a plan view illustrating an LDMOSFET 300 according to the third embodiment.

In FIG. 33, in the third embodiment, the n-type semiconductor region NR is formed in not only the portion of the epitaxial layer EPI but also the second portion P2 of the p-type well PWL. For example, as illustrated in FIG. 33, the n-type semiconductor region NR is formed in the portion of the epitaxial layer EPI in the X-direction located between the offset drain region OD and the source region SR. As illustrated in FIG. 33, the n-type semiconductor region NR is formed in the portion of the epitaxial layer EPI in the X-direction located between the offset drain region OD and the second portion P2 of the p-type well PWL and in the second portion P2 of the p-type well PWL. That is, in a portion of the LDMOSFET 300 along a line A-A illustrated in FIG. 33, the n-type semiconductor region NR is formed in the portion of the epitaxial layer EPI located between the offset drain region OD and the second portion P2 of the p-type well PWL. In a portion of the LDMOSFET 300 along a line B-B illustrated in FIG. 33, the n-type semiconductor region NR is also formed in the portion of the epitaxial layer EPI located between the offset drain region OD and the second portion P2 of the p-type well PWL and in the second portion P2 of the p-type well PWL.

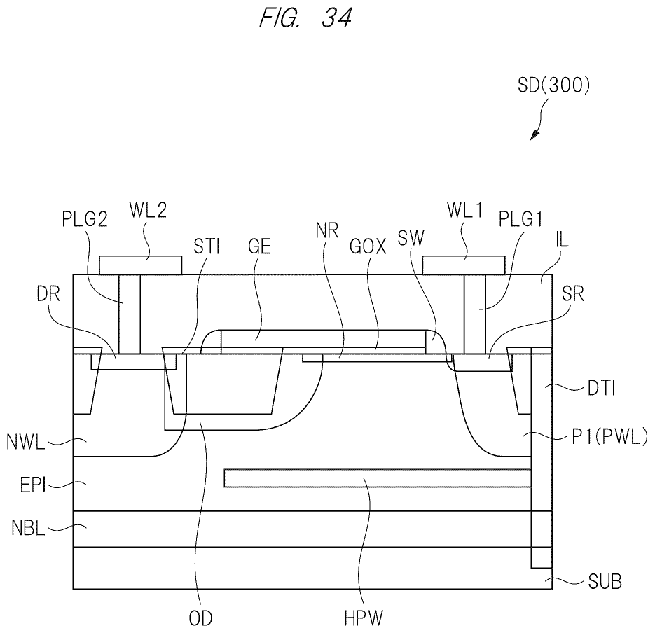

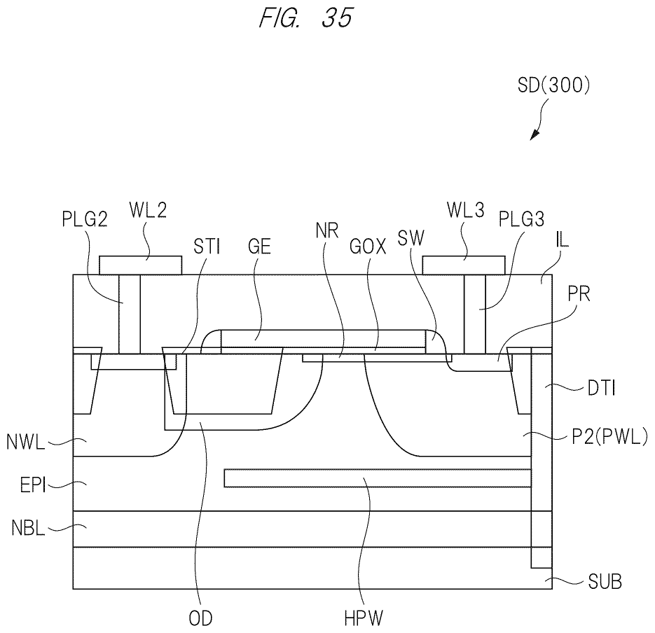

FIG. 34 is a cross-sectional view of the LDMOSFET along the line A-A illustrated in FIG. 33. FIG. 34 is similar to FIG. 14. Accordingly, description of FIG. 34 is omitted. FIG. 35 is a cross-sectional view of the LDMOSFET along the line B-B illustrated in FIG. 33. As illustrated in FIG. 35, the n-type semiconductor region NR is formed in not only the portion of the epitaxial layer EPI located between the offset drain region OD and the second portion P2 of the p-type well PWL but also the second portion P2 of the p-type well PWL. Thus, in the third embodiment, the n-type impurity concentration of the n-type semiconductor region NR is higher than the p-type impurity concentration of the p-type well PWL.

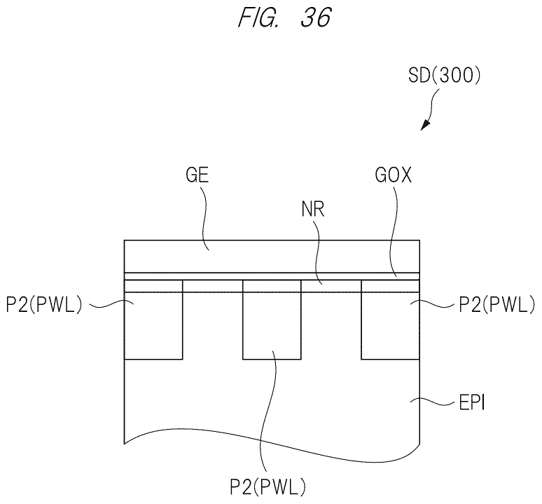

FIG. 36 is a cross-sectional view of the LDMOSFET along a line C-C illustrated in FIG. 33. As illustrated in FIG. 36, the n-type semiconductor region NR is formed in the portion of the epitaxial layer EPI located between the second portions P2 of the p-type well PWL spaced apart at a predetermined interval and in the second portion P2 of the p-type well PWL. Here, the p-type impurity concentration of the p-type well PWL is higher than the p-type impurity concentration of the epitaxial layer EPI. Therefore, the n-type impurity concentration of the n-type semiconductor region NR formed in the second portion P2 of the p-type well PWL is lower than the n-type impurity concentration of the n-type semiconductor region NR formed in the epitaxial layer EPI.

The semiconductor device SD in the third embodiment is configured as described above.

Next, the n-type impurity concentration of the n-type semiconductor region NR will be described.

Specifically, a relationship among the n-type impurity concentration of the n-type semiconductor region NR in the first embodiment, the n-type impurity concentration of the n-type semiconductor region NR in the third embodiment, and the n-type impurity concentration of the n-type semiconductor region NR in the first related technique will be described.

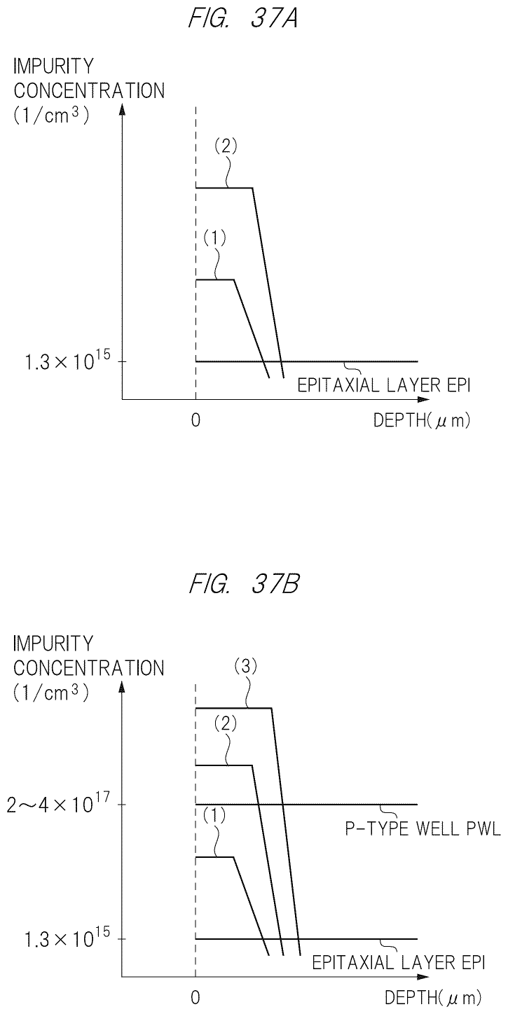

FIG. 37A is a diagram illustrating an impurity profile in the epitaxial layer EPI in a depth direction in each of FIG. 14 illustrating the first embodiment and FIG. 34 illustrating the third embodiment.

In FIG. 37A, a horizontal axis indicates a depth from an upper surface of the epitaxial layer EPI. A vertical axis indicates the impurity concentration of the p-type impurities or the n-type impurities.

In FIG. 37A, the p-type impurity concentration of the epitaxial layer EPI is, for example, 1.3×10¹⁵ (1/cm³). “(1)” indicates an n-type impurity profile of the n-type semiconductor region NR in the first embodiment illustrated in FIG. 14. “(2)” indicates an n-type impurity profile of the n-type semiconductor region NR in the third embodiment illustrated in FIG. 34.

As illustrated in FIG. 37A, both the n-type impurity concentration of the n-type semiconductor region NR in the first embodiment and the n-type impurity concentration of the n-type semiconductor region NR in the third embodiment are higher than the p-type impurity concentration of the epitaxial layer EPI. The n-type impurity concentration of the n-type semiconductor region NR in the first embodiment is lower than the n-type impurity concentration of the n-type semiconductor region NR in the third embodiment. As a result, the dose amount of the n-type impurities to be introduced into the epitaxial layer EPI to form the n-type semiconductor region NR in the first embodiment is lower than that in the third embodiment. Accordingly, the dose amount of the n-type impurities to be introduced into the offset drain region OD in the first embodiment can be made lower than that in the third embodiment. Therefore, the decrease in the breakdown voltage of the LDMOSFET due to the introduction of the n-type impurities into the offset drain region OD in the first embodiment is more easily suppressed than that in the third embodiment.

FIG. 37B is a diagram illustrating an impurity profile in the epitaxial layer EPI in the depth direction in each of FIG. 15 illustrating the first embodiment and FIG. 35 illustrating the third embodiment.

In FIG. 37B, a horizontal axis indicates the depth from the upper surface of the epitaxial layer EPI. A vertical axis indicates the impurity concentration of the p-type impurities or the n-type impurities.

In FIG. 37B, the p-type impurity concentration of the epitaxial layer EPI is, for example, 1.3×10¹⁵ (1/cm³). The p-type impurity concentration of the p-type well PWL is, for example, equal to or more than 2×10¹⁷ (1/cm³) and equal to or less than 4×10¹⁷ (1/cm³). Therefore, the p-type impurity concentration of the p-type well PWL is higher than the p-type impurity concentration of the epitaxial layer EPI. “(1)” indicates an n-type impurity profile of the n-type semiconductor region NR in the first embodiment illustrated in FIG. 15. “(2)” indicates an n-type impurity profile of the n-type semiconductor region NR in the third embodiment illustrated in FIG. 35. “(3)” indicates an n-type impurity profile of the n-type semiconductor region NR in the first related technique illustrated in FIG. 7.

As illustrated in FIG. 37B, both the n-type impurity concentration of the n-type semiconductor region NR in the first embodiment and the n-type impurity concentration of the n-type semiconductor region NR in the third embodiment are higher than the p-type impurity concentration of the epitaxial layer EPI. The n-type impurity concentration of the n-type semiconductor region NR in the first embodiment is lower than the p-type impurity concentration of the p-type well PWL. Accordingly, the n-type semiconductor region NR in the first embodiment is not formed in the p-type well PWL. On the other hand, the n-type impurity concentration of the n-type semiconductor region NR in the third embodiment is higher than the p-type impurity concentration of the p-type well PWL. Accordingly, the n-type semiconductor region NR in the third embodiment is also formed in the p-type well PWL.

The n-type impurity concentration of the n-type semiconductor region NR in the first related technique is higher than the p-type impurity concentration of the p-type well PWL. Therefore, even in the first related technique, the n-type semiconductor region NR is also formed in the p-type well PWL. The n-type impurity concentration of the n-type semiconductor region NR in the first related technique is higher than the n-type impurity concentration of the n-type semiconductor region NR in the third embodiment. Therefore, the dose amount of the n-type impurities to be introduced into the epitaxial layer EPI to form the n-type semiconductor region NR in the third embodiment is lower than that in the first related technique. Accordingly, the third embodiment can more decrease the dose amount of the n-type impurities to be introduced into the offset drain region OD than that in the first related technique. Therefore, the third embodiment can more suppress the decrease in the breakdown voltage of the LDMOSFET due to the introduction of the n-type impurities into the offset drain region OD than that in the first related technique.

### Features in Third Embodiment

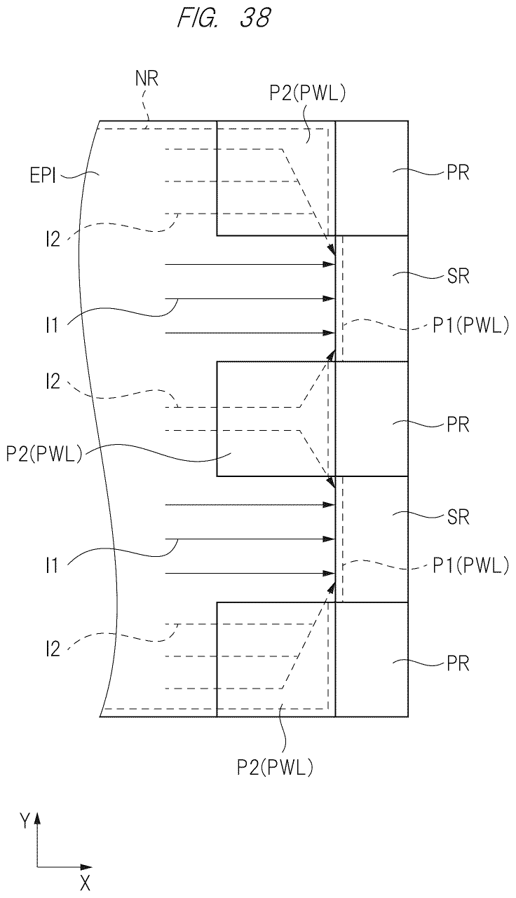

FIG. 38 is a diagram illustrating a main current I1 and a sub-current I2 flowing from the drain region DR to the source region SR in the LDMOSFET including the n-type semiconductor region NR and the p-type well PWL made of the “ladder structure” having the first portion P1 and the second portion P2.

In FIG. 38, the main current I1 illustrated with a solid line indicates a current flowing to the source regions SR from the n-type semiconductor region NR formed in the portion of the epitaxial layer EPI located between the offset drain region (not illustrated in FIG. 38) and the source region SR.

On the other hand, the sub-current I2 illustrated with a broken line indicates a current flowing to the source regions SR via the n-type semiconductor region NR formed in the portion of the epitaxial layer EPI located between the offset drain region (not illustrated in FIG. 38) and the second portion P2 of the p-type well PWL and the n-type semiconductor region NR formed in the second portion P2 of the p-type well PWL.

In the third embodiment, the n-type semiconductor region NR is also formed in the second portion P2 of the p-type well PWL. Accordingly, the sub-current I2 is larger than that in a configuration in which the n-type semiconductor region NR is not formed in the second portion P2 of the p-type well PWL. Therefore, according to the third embodiment, a total current amount of the main current I1 and the sub-current I2 can be increased. That is, according to the third embodiment, a current driving force of the LDMOSFET can be improved.

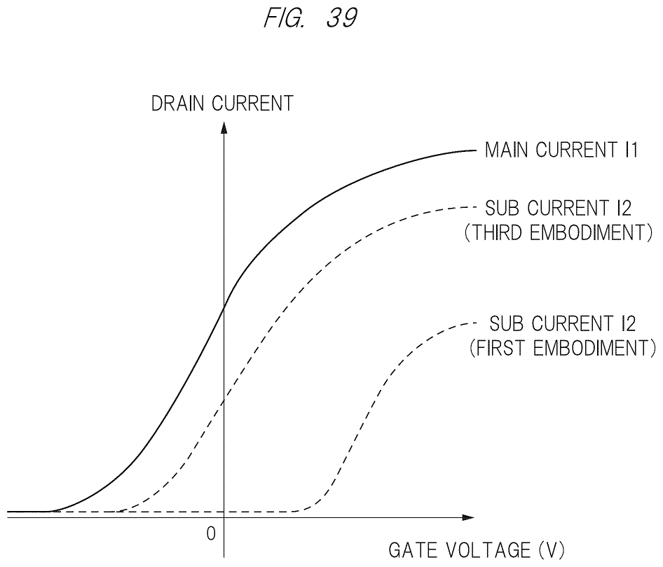

FIG. 39 is a diagram qualitatively explaining in the third embodiment that the total current amount of the main current I1 and the sub-current I2 can be increased.

For example, in the configuration in which the n-type semiconductor region NR is not formed in the second portion P2 of the p-type well PWL (the configuration in the first embodiment), an inversion layer needs to be formed in the second portion P2 of the p-type well PWL in order to cause the sub-current I2 to flow. That is, the threshold voltage for forming the inversion layer in the second portion P2 of the p-type well PWL is the positive voltage.

On the other hand, in the configuration in which the n-type semiconductor region NR is formed in the second portion P2 of the p-type well PWL (the configuration in the third embodiment), the n-type semiconductor region NR is formed in the second portion P2 of the p-type well PWL. Accordingly, even if the inversion layer is not formed in the second portion P2 of the p-type well PWL, the sub-current I2 can be caused to flow. That is, in the third embodiment, the positive voltage may not be applied to the gate electrode in order to cause the sub-current I2 to flow. That is, in the third embodiment, even if the gate voltage to be applied to the gate electrode is the negative voltage, the sub-current I2 flows.

As a result, as illustrated in FIG. 39, the sub-current I2 flowing in the configuration in the third embodiment is larger than the sub-current I2 flowing in the configuration in the first embodiment. Thus, based on FIG. 39, according to the third embodiment, the total current amount of the main current I1 and the sub-current I2 can be increased.

In each of the first embodiment, the modification example of the first embodiment, the second embodiment, and the third embodiment, the stacked structure including the semiconductor substrate SUB and the epitaxial layer EPI formed on the semiconductor substrate SUB has been described. However, the epitaxial layer EPI may not be formed.

When the epitaxial layer EPI is not formed, the n-type buried layer NBL, the deep p-type well HPW, the n-type well NWL, the drain region DR, the trench region STI, the deep trench region DTI, the offset drain region OD, the p-type well PWL, the n-type semiconductor region NR, the body contact regions PR, and the source regions SR are formed in the semiconductor substrate SUB. The gate insulating film GOX, the gate electrode GE, the sidewall spacer SW, the interlayer insulating film IL, the plug PLG1, the plug PLG2, the plug PLG3, the wiring WL1, the wiring WL2, the wiring WL3, and the wiring WL are formed on the semiconductor substrate SUB.

If the epitaxial layer EPI is not formed, the first embodiment, the modification example to the first embodiment, the second embodiment, and the third embodiment can be understood when the epitaxial layer EPI is replaced with the semiconductor substrate SUB.

In the foregoing, the invention made by the present inventors has been concretely described based on the embodiments. However, it is needless to say that the present invention is not limited to the foregoing embodiments, and various modifications can be made within the scope of the present invention.

What is claimed is:

1. A semiconductor device comprising:
a semiconductor substrate of a first conductivity type;
a first well of the first conductivity type formed in the semiconductor substrate, the first well having a higher impurity concentration than an impurity concentration of the semiconductor substrate, the first well having a first portion and a second portion;
an offset drain region of a second conductivity type opposite the first conductivity type formed in the semiconductor substrate, the offset drain region being spaced apart from the first well;
a drain region of the second conductivity type formed in the offset drain region, the drain region having a higher impurity concentration than an impurity concentration of the offset drain region;
a source region of the second conductivity type formed in the semiconductor substrate to partially overlap the first portion of the first well, the source region being spaced apart from the offset drain region;
a gate insulating film formed on the semiconductor substrate; and
a gate electrode formed on the gate insulating film,
wherein, in a gate length direction of the gate electrode, a first distance between the offset drain region and the first portion of the first well is larger than a second distance between the offset drain region and the second portion of the first well, and
wherein the semiconductor device comprising:
a first semiconductor region of the second conductivity type formed in a portion of the semiconductor substrate located between the offset drain region and the source region.

2. The semiconductor device according to claim 1,
wherein the first semiconductor region is formed in a portion of the semiconductor substrate located between the offset drain region and the second portion of the first well.

3. The semiconductor device according to claim 2,
wherein the first semiconductor region extends into the first well.

4. The semiconductor device according to claim 1,
wherein the first semiconductor region is arranged not to be formed in a portion of the semiconductor substrate located between the offset drain region and the second portion of the first well.

5. The semiconductor device according to claim 1,
wherein an impurity concentration of the first semiconductor region is higher than the impurity concentration of the semiconductor substrate.

6. The semiconductor device according to claim 5,
wherein the impurity concentration of the first semiconductor region is lower than the impurity concentration of the first well.

7. The semiconductor device according to claim 5,
wherein the impurity concentration of the first semiconductor region is higher than the impurity concentration of the first well.

8. The semiconductor device according to claim 1,
wherein the first conductivity type is a p-type,
wherein the second conductivity type is an n-type,
wherein the gate electrode is a gate electrode of an n-channel type field effect transistor, and
wherein the n-channel type field effect transistor has a negative threshold voltage.

9. The semiconductor device according to claim 1,
wherein the semiconductor device has a trench formed in the offset drain region, and
wherein the trench is filled with an insulating material.

10. The semiconductor device according to claim 1,
wherein the first portion of the first well and the second portion of the first well are adjacent to each other in a gate width direction of the gate electrode.

11. The semiconductor device according to claim 1, further comprising:
a body contact region of the first conductivity type formed in the first well, the body contact region having a higher impurity concentration than the impurity concentration of the first well, and the body contact region being in contact with the source region.

12. The semiconductor device according to claim 11,
wherein the source region and the body contact region are adjacent to each other in a gate width direction of the gate electrode.

13. The semiconductor device according to claim 11,
wherein the source region and the body contact region are adjacent to each other in the gate length direction of the gate electrode.
